(19) United States
(12) Patent Application Publication
(10) Pub. No.: US 2026/0143932 A1
(43) Pub. Date: May 21, 2026

(54) DISPLAY SUBSTRATE AND DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Ying HAN, Beijing (CN); Pan XU, Beijing (CN); Xing ZHANG, Beijing (CN); Chengyuan LUO, Beijing (CN); Guangshuang LV, Beijing (CN); Donghui ZHAO, Beijing (CN); Cheng XU, Beijing (CN); Hongli WANG, Beijing (CN); Tong WU, Beijing (CN); Dandan ZHOU, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/705,902

(22) PCT Filed: May 23, 2023
(86) PCT No.: PCT/CN2023/095842

§ 371 Date: Apr. 29, 2024

(30) Foreign Application Priority Data
Nov. 28, 2022 (WO) PCT/CN2022/134711

(51) Int. Cl. H10K 59/131; H10K 50/858; H10K 59/121; H10K 59/123; H10K 59/35; H10K 59/80

(52) U.S. Cl. CPC H10K 59/131; H10K 50/858; H10K 59/1213; H10K 59/1216; H10K 59/123; H10K 59/353; H10K 59/879

(57) ABSTRACT

At least one embodiments of the present disclosure provides a display substrate and a display device, the display substrate includes a base substrate, sub-pixels, and signal lines; the sub-pixels arranged in an array along a first direction and a second direction on the base substrate and include pixel circuits, each of the sub-pixels includes display units, each of the display units is independently driven by a corresponding pixel circuit, and adjacent display units form a pixel unit group; at least part of the signal line extends along the second direction, display units in at least one pixel unit group are connected to a same signal line, and in the second direction, the signal line includes a first connection portion and a second connection portion, and in the first direction, a width of the first connection portion is less than a width of the second connection portion.

### CROSS-REFERENCE TO RELATED APPLICATION

The present application claims the priority to PCT patent application No. PCT/CN2022/134711, filed on Nov. 28, 2022, the entire disclosure of which is incorporated herein by reference as a part of the present application.

### TECHNICAL FIELD

Embodiments of the present disclosure relate to a display substrate and a display device.

### BACKGROUND

Compared with traditional liquid crystal display devices, the active matrix organic light-emitting diode (AMOLED) has wider viewing angle, wider color gamut, higher contrast, higher refresh rate, lower power consumption and thinner size. The AMOLED screen is very thin and can integrate a touch layer into the screen, which has more advantages in manufacturing ultra-thin devices. High-resolution AMOLED uses a pixel arrangement, which is different from the liquid crystal display devices. In the liquid crystal display devices, one pixel is equal to the collection of three sub-pixels of red, green and blue. In AMOLED devices, green is greatly emphasized, making the picture look more vivid. AMOLED is self-luminous, and individual pixels do not work when displaying black, and consume less power when displaying dark colors. Therefore, AMOLED saves power in dark colors, has a contrast ratio hundreds of times that of LCD devices, and does not leak light. AMOLED has a certain degree of flexibility. Compared with liquid crystal display devices with glass substrates, AMOLED screens are less likely to be damaged. Therefore, AMOLEDs are widely used in small and medium-sized display devices.

### SUMMARY

At least one embodiment of the present disclosure provides a display substrate and a display device. The display substrate enables display units included in at least one pixel unit group to be connected to the same signal line, and the signal line extending in the second direction includes a first connection portion and a second connection portion that have different widths in the first direction, the width of the first connection portion is less than the width of the second connection portion, which can increase the spacing between structures in the same layer, reduce process defects, and reduce the load on the signal line.

At least one embodiment of the present disclosure provides a display substrate, the display substrate includes: a base substrate; a plurality of sub-pixels, arranged in an array along a first direction and a second direction that intersect each other on the base substrate, and comprising a plurality of pixel circuits, in which each of the sub-pixels comprises a plurality of display units, each of the display units is independently driven by a corresponding pixel circuit, and adjacent display units form a pixel unit group; and a plurality of signal lines, in which at least part of the signal line extends along the second direction, display units comprised in at least one pixel unit group are connected to a same signal line, and in the second direction, the signal line comprises a first connection portion and a second connection portion, and in the first direction, a width of the first connection portion is less than a width of the second connection portion.

For example, in the display substrate provided by at least one embodiment of the present disclosure, the display substrate comprises a first conductive layer and a functional layer stacked on the base substrate, the first conductive layer comprises a plurality of conductive structures arranged in the second direction, each of the conductive structures comprises a conductive portion electrically connected to the functional layer through a via structure, and conductive portions adjacent to each other in the second direction are spaced apart in the first direction.

For example, in the display substrate provided by at least one embodiment of the present disclosure, the functional layer comprises a semiconductor layer, a first metal layer, and a second conductive layer stacked on the base substrate; the conductive structure comprises a first conductive structure, a second conductive structure, a third conductive structure, a fourth conductive structure, a fifth conductive structure, a sixth conductive structure, a seventh conductive structure, an eighth conductive structure, a ninth conductive structure, a tenth conductive structure, and an eleventh conductive structure arranged sequentially in the second direction; the conductive portion comprises a first conductive portion, a second conductive portion, a third conductive portion, a fourth conductive portion, a fifth conductive portion, a sixth conductive portion, a seventh conductive portion, an eighth conductive portion, a ninth conductive portion, a tenth conductive portion, and an eleventh conductive portion; and the first conductive portion, the second conductive portion, the third conductive portion, the fourth conductive portion, the fifth conductive portion, the sixth conductive portion, the seventh conductive portion, the eighth conductive portion, the ninth conductive portion, the tenth conductive portion, and the eleventh conductive portion are respectively a part of the first conductive structure, the second conductive structure, the third conductive structure, the fourth conductive structure, the fifth conductive structure, the sixth conductive structure, the seventh conductive structure, the eighth conductive structure, the ninth conductive structure, the tenth conductive structure, and the eleventh conductive structure; the via structure comprises a first via structure, a second via structure, a third via structure, a fourth via structure, a fifth via structure, a sixth via structure, a seventh via structure, an eighth via structure, a ninth via structure, a tenth via structure, and an eleventh via structure; the first conductive portion is electrically connected to the semiconductor layer through the first via structure, the second conductive portion is electrically connected to the first metal layer through the second via structure, the third conductive portion is electrically connected to the semiconductor layer through the third via structure, the fourth conductive portion is electrically connected to the first metal layer through the fourth via structure, the fifth conductive portion is electrically connected to the second conductive layer through the fifth via structure, the sixth conductive portion is electrically connected to the first metal layer through the sixth via structure, the seventh conductive portion is electrically connected to the first metal layer through the seventh via structure, the eighth conductive portion is electrically connected to the semiconductor layer through the eighth via structure, the ninth conductive portion is electrically connected to the first metal layer through the ninth via structure, the tenth conductive portion is electrically connected to the first metal layer through the tenth via structure, and the eleventh conductive portion is electrically connected to the second conductive layer through the eleventh via structure; and any two adjacent portions among the first conductive portion, the second conductive portion, the third conductive portion, the fourth conductive portion, the fifth conductive portion, the sixth conductive portion, the seventh conductive portion, the eighth conductive portion, the ninth conductive portion, the tenth conductive portion, and the eleventh conductive portion in the second direction are spaced apart in the first direction.

For example, in the display substrate provided by at least one embodiment of the present disclosure, each of the first conductive structure, the second conductive structure, the third conductive structure, the fourth conductive structure, the seventh conductive structure, the eighth conductive structure, the ninth conductive structure, and the tenth conductive structure is in a shape of a long strip extending in the first direction; a width of the first conductive portion in the second direction is greater than widths of other parts of the first conductive structure in the second direction, a width of the second conductive portion in the second direction is greater than widths of other parts of the second conductive structure in the second direction, a width of the third conductive portion in the second direction is greater than widths of other parts of the third conductive structure in the second direction, a width of the fourth conductive portion in the second direction is greater than widths of other parts of the fourth conductive structure in the second direction, a width of the seventh conductive portion in the second direction is greater than widths of other parts of the seventh conductive structure in the second direction, a width of the eighth conductive portion in the second direction is greater than widths of other parts of the eighth conductive structure in the second direction, a width of the ninth conductive portion in the second direction is greater than widths of other parts of the ninth conductive structure in the second direction, and a width of the tenth conductive portion in the second direction is greater than widths of other parts of the tenth conductive structure in the second direction.

For example, in the display substrate provided by at least one embodiment of the present disclosure, the fifth conductive structure, the sixth conductive structure, and the eleventh conductive structure each comprise block structures spaced apart from each other in the first direction, the fifth conductive portion is at a middle position of respective block structures comprised in the fifth conductive structure, the sixth conductive portion is at a middle position of respective block structures comprised in the sixth conductive structure, and the fifth conductive portion and the sixth conductive portion are arranged in a staggered manner in the first direction; and in each of block structures comprised in the eleventh conductive structure, two eleventh conductive portions are respectively at both ends of a corresponding block structure along the first direction.

For example, in the display substrate provided by at least one embodiment of the present disclosure, in the first direction, the first conductive portion, the second conductive portion, the third conductive portion, the fourth conductive portion, the fifth conductive portion, the sixth conductive portion, the seventh conductive portion, the eighth conductive portion, and the eleventh conductive portion comprised in any two adjacent display units are all axially symmetrical with respect to a straight line that is between the two adjacent display units and extending in the second direction.

For example, in the display substrate provided by at least one embodiment of the present disclosure, among the two adjacent display units in the first direction, one is electrically connected to the ninth conductive structure, and the other is electrically connected to the tenth conductive structure; and in the second direction, spacing between the ninth conductive structure and the tenth conductive structure is greater than spacing between the ninth conductive structure and the eighth conductive structure, and also greater than spacing between the tenth conductive structure and the eleventh conductive structure.

For example, the display substrate provided by at least one embodiment of the present disclosure further comprises a lens structure, configured to irradiate image light emitted from the plurality of sub-pixels to different viewpoint regions, in which the lens structure comprises a plurality of lens portions arranged in the first direction and extending in the second direction; and the plurality of sub-pixels are arranged into a plurality of sub-pixel row groups, the plurality of sub-pixel row groups extend in the second direction and are arranged in the first direction, each of the sub-pixel row groups comprises at least two rows of sub-pixels, each of the sub-pixel row groups corresponds to one of the plurality of lens portions, and a plurality of viewpoint regions formed by respective sub-pixel row groups through corresponding lens portions are continuously arranged along the first direction.

For example, in the display substrate provided by at least one embodiment of the present disclosure, each of the sub-pixel row groups comprises a first color sub-pixel, a second color sub-pixel, and a third color sub-pixel, sub-pixels in a same row and arranged along the first direction are sub-pixels of a same color, a first color sub-pixel row, a second color sub-pixel row and a third color sub-pixel row are arranged sequentially and repeatedly along the second direction, and each of the sub-pixel row groups comprises 3N rows of sub-pixels, where N is a positive integer.

For example, in the display substrate provided by at least one embodiment of the present disclosure, each display unit comprises a light-emitting element, the light-emitting element is electrically connected to a corresponding pixel circuit, the pixel circuit is configured to drive the light-emitting element, and the light-emitting element comprises a first electrode, a second electrode, and a light-emitting functional layer between the first electrode and the second electrode; and the pixel circuit comprises a driving circuit, the driving circuit comprises a driving transistor, and the first electrode of the light-emitting element is electrically connected to a first electrode of the driving transistor.

For example, in the display substrate provided by at least one embodiment of the present disclosure, the pixel circuit further comprises a light-emitting control circuit, a data writing circuit, a first reset circuit, and a second reset circuit; the light-emitting control circuit comprises a light-emitting control transistor, the data writing circuit comprises a data writing transistor, the first reset circuit comprises a first reset transistor, and the second reset circuit comprises a second reset transistor; the light-emitting control transistor is electrically connected to a second electrode of the driving transistor and is configured to transmit a first power supply voltage to the second transistor of the driving transistor in response to a light-emitting control signal; the data writing transistor is electrically connected to a gate electrode of the driving transistor and is configured to write a data signal into the gate electrode of the driving transistor in response to a first scanning signal; the first reset transistor is electrically connected to the gate electrode of the driving transistor and is configured to transmit a reference voltage to the gate electrode of the driving transistor in response to a second scanning signal; and the second reset transistor is electrically connected to the first electrode of the light-emitting element and is configured to transmit an initialization voltage to the first electrode of the light-emitting element in response to a third scanning signal.

For example, in the display substrate provided by at least one embodiment of the present disclosure, the pixel circuit further comprises a first storage circuit and a second storage circuit; the first storage circuit comprises a first capacitor, the second storage circuit comprises a second capacitor, a first electrode plate of the first capacitor is electrically connected to the gate electrode of the driving transistor, a second electrode plate of the first capacitor is electrically connected to the first transistor of the driving transistor, and the first capacitor is configured to store the data signal; and a first electrode plate of the second capacitor is electrically connected to the first electrode of the light-emitting element, and a second electrode plate of the second capacitor is electrically connected to the second electrode of the light-emitting element.

For example, in the display substrate provided by at least one embodiment of the present disclosure, the second conductive layer comprises the signal lines, and the signal lines comprise a first power supply voltage signal line and a data line arranged in the first direction, and a connection structure provided in a gap between the first power supply voltage signal line and the data line that are adjacent to each other; the first power supply voltage signal line and the data line both extend along the second direction, and a plurality of first power supply voltage signal lines and a plurality of data lines are alternately arranged in the first direction; and the first power supply voltage signal line is configured to provide the first power supply voltage to the sub-pixel, the data line is configured to provide the data signal to the pixel circuit, and the connection structure is configured to be electrically connected to the first conductive layer.

For example, in the display substrate provided by at least one embodiment of the present disclosure, a part of the first power supply voltage signal line corresponding to the connection structure is the first connection portion, and a part of the first power supply voltage signal line other than the first connection portion is the second connection portion; and a part of the data line corresponding to the connection structure is the first connection portion, and a part of the data line other than the first connection portion is the second connection portion.

For example, in the display substrate provided by at least one embodiment of the present disclosure, in the first direction, a width of the connection structure between the first power supply voltage signal line and the data line that are adjacent to each other is less than a maximum distance between the first power supply voltage signal line and the data line that are adjacent to each other, and greater than a minimum distance between the first power supply voltage signal line and the data line that are adjacent to each other.

For example, in the display substrate provided by at least one embodiment of the present disclosure, the first conductive structure, the second conductive structure, the third conductive structure, the fourth conductive structure, the fifth conductive structure, the sixth conductive structure, the seventh conductive structure, the eighth conductive structure, the ninth conductive structure, the tenth conductive structure, and the eleventh conductive structure are respectively a reference voltage signal line, a second gate line, an initialization signal line, a third gate line, a connection portion of a first electrode of the second reset transistor, a connection portion of a first electrode of the driving transistor, a light-emitting control line, a first power supply voltage signal line connection line, a first gate line portion, a second gate line portion, and a data line connection line; and the initialization signal line is configured to provide an initialization voltage to the sub-pixel, the reference voltage signal line is configured to provide a reference voltage to the sub-pixel, the first power supply voltage signal line connection line is configured to electrically connect first power supply voltage signal lines arranged in the first direction, the light-emitting control line is configured to provide a light-emitting control signal to the pixel circuit, and the data line connection line is configured to connect data lines that are adjacent in the first direction and extend in the second direction.

For example, in the display substrate provided by at least one embodiment of the present disclosure, the first metal layer comprises a gate electrode of the first reset transistor, a gate electrode of the second reset transistor, the gate electrode of the driving transistor, a gate electrode of the light-emitting control transistor, as well as a gate electrode of the data writing transistor comprised in one of adjacent display units and a gate electrode of the data writing transistor comprised in the other of the adjacent display units, which are arranged sequentially in the second direction; the gate electrode of the data writing transistor comprised in one of the adjacent display units is electrically connected to the first gate line portion, or the gate electrode of the data writing transistor comprised in the other of the adjacent display units is electrically connected to the second gate line portion; the gate electrode of the first reset transistor is electrically connected to the second gate line, and a first electrode of the first reset transistor is electrically connected to the reference voltage signal line; the gate electrode of the second reset transistor is electrically connected to the third gate line, a second electrode of the second reset transistor is electrically connected to the initialization signal line; and the gate electrode of the light-emitting control transistor is electrically connected to the light-emitting control line, and a first electrode of the light-emitting control transistor is electrically connected to the first power supply voltage signal line.

For example, in the display substrate provided by at least one embodiment of the present disclosure, the gate electrode of the data writing transistor comprised in one of the adjacent display units, and the gate electrode of the data writing transistor comprised in the other of the adjacent display units are spaced apart from each other in the first direction.

For example, in the display substrate provided by at least one embodiment of the present disclosure, the gate electrode of the first reset transistor is in a shape of a long strip and extends in the first direction, and an orthographic projection of the second gate line on the base substrate is within an orthographic projection of the gate electrode of the first reset transistor on the base substrate.

For example, in the display substrate provided by at least one embodiment of the present disclosure, in the second direction, the orthographic projection of the gate electrode of the first reset transistor on the base substrate is between an orthographic projection of the reference voltage signal line on the base substrate and an orthographic projection of the initialization signal line on the base substrate; and an orthographic projection of the gate electrode of the second reset transistor on the base substrate is on a side of the orthographic projection of the initialization signal line on the base substrate away from the orthographic projection of the reference voltage signal line on the base substrate.

For example, in the display substrate provided by at least one embodiment of the present disclosure, the semiconductor layer comprises a first active portion, a second active portion, a third active portion, a fourth active portion, and a fifth active portion; an orthographic projection of the first active portion on the base substrate overlaps with an orthographic projection of the first gate line on the base substrate, an orthographic projection of the second active portion on the base substrate overlaps with the orthographic projection of the second gate line on the base substrate, an orthographic projection of the third active portion on the base substrate overlaps with an orthographic projection of the third gate line on the base substrate, an orthographic projection of the fourth active portion on the base substrate overlaps with an orthographic projection of the light-emitting control line on the base substrate, and an orthographic projection of the fifth active portion on the base substrate overlaps with an orthographic projection of the gate electrode of the driving transistor on the base substrate; and each of the first active portion, the second active portion, the third active portion, the fourth active portion, and the fifth active portion extends along the second direction and comprises a channel, and a first electrode and a second electrode on both sides of the channel.

For example, in the display substrate provided by at least one embodiment of the present disclosure, in the semiconductor layer corresponding to each display unit, the first active portion and the second active portion are in an integrated structure, and the third active portion, the fourth active portion, and the fifth active portion are in an integrated structure.

For example, the display substrate provided by at least one embodiment of the present disclosure further comprises a display region and a peripheral region surrounding a periphery of the display region, in the display region, first electrodes of two light-emitting elements adjacent in the first direction have first spacing in the first direction, first electrodes of two light-emitting elements adjacent in the second direction have second spacing in the second direction, and the first spacing is less than the second spacing.

For example, in the display substrate provided by at least one embodiment of the present disclosure, in the peripheral region, the spacing between the first electrodes of two light-emitting elements adjacent in the second direction increases in a direction away from the display region.

At least one embodiment of the present disclosure provides a display device, the display device comprises the display substrate according to any one of the above embodiments.

### BRIEF DESCRIPTION OF DRAWINGS

In order to clearly illustrate technical solutions of the embodiments of the present disclosure, the drawings of the embodiments will be briefly described. It is obvious that the described drawings in the following are only related to some embodiments of the present disclosure and thus are not construed as any limitation to the present disclosure.

FIG. 1 is a schematic diagram of a planar structure of a pixel layout of a display substrate;

FIG. 2 is a schematic diagram of a pixel layout of a display substrate provided by at least one embodiment of the present disclosure;

FIG. 3 is a circuit diagram of a display unit in a display substrate provided by at least one embodiment of the present disclosure;

FIG. 4 is a timing signal diagram of a display unit of a display substrate provided by embodiments of the present disclosure;

FIG. 5 is a timing signal diagram of a display unit of a display substrate provided by embodiments of the present disclosure;

FIG. 6 is a schematic diagram of a transistor turning-on/off during a reset stage of a display unit of a display substrate provided by embodiments of the present disclosure;

FIG. 7 is a schematic diagram of a transistor turning-on/off during a compensation stage of a display unit of a display substrate provided by embodiments of the present disclosure;

FIG. 8 is a schematic diagram of a transistor turning-on/off during a data writing stage of a display unit of a display substrate provided by embodiments of the present disclosure;

FIG. 9 is a schematic diagram of a transistor turning-on/off during a light-emitting stage of a display unit of a display substrate provided by embodiments of the present disclosure;

FIG. 10 is a circuit diagram of a plurality of display units of a display substrate provided by at least one embodiment of the present disclosure;

FIG. 11 is a schematic diagram of a planar structure of a semiconductor layer provided by at least one embodiment of the present disclosure;

FIG. 12 is a schematic diagram of a planar structure of a first metal layer provided by at least one embodiment of the present disclosure;

FIG. 13 is a schematic diagram of a stacked layers structure including a semiconductor layer and a first metal layer provided by at least one embodiment of the present disclosure;

FIG. 14 is a schematic diagram of a planar structure of a second metal layer provided by at least one embodiment of the present disclosure;

FIG. 15 is a schematic diagram of a planar structure of an interlayer insulation layer provided by at least one embodiment of the present disclosure;

FIG. 16 is a schematic diagram of a stacked layers structure including a semiconductor layer, a first metal layer, a second metal layer, and an interlayer insulation layer provided by at least one embodiment of the present disclosure;

FIG. 17 is a schematic diagram of a planar structure of a first conductive layer provided by at least one embodiment of the present disclosure;

FIG. 18 is a schematic diagram of a planar structure of a second conductive layer provided by at least one embodiment of the present disclosure;

FIG. 19 is a schematic diagram of planar structures of a first planarization layer, a first passivation layer, a second planarization layer, and a second passivation layer provided by at least one embodiment of the present disclosure;

FIG. 20 is a schematic diagram of a stacked layers structure including a semiconductor layer, a first metal layer, a second metal layer, a first conductive layer, and a second conductive layer corresponding to a plurality of sub-pixels in a display substrate provided by at least one embodiment of the present disclosure;

FIG. 21 is a simplified schematic diagram of a planar structure of a display substrate provided by at least one embodiment of the present disclosure;

FIG. 22 is a schematic diagram of a planar structure of another display substrate provided by at least one embodiment of the present disclosure;

FIG. 23 is an enlarged schematic diagram of four display units in FIG. 20;

FIG. 24 is a schematic diagram of a planar structure of a display substrate provided by at least one embodiment of the present disclosure;

FIG. 25 is a schematic diagram of a planar structure of a first electrode of a light-emitting element provided by at least one embodiment of the present disclosure;

FIG. 26 is a schematic diagram of a cross-sectional structure of a display substrate provided by at least one embodiment of the present disclosure; and

FIG. 27 is a schematic diagram of a planar structure of a display device provided by at least one embodiment of the present disclosure.

### DETAILED DESCRIPTION

In order to make objectives, technical details, and advantages of the embodiments of the present disclosure clearer, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “left,” “right” and the like are only used to indicate relative position relationship, and when the position of the object which is described is changed, the relative position relationship may be changed accordingly.

Ultra-high-resolution display technology can improve the display effect of the display screen. The ultra-high-resolution display device may be used in a variety of special displays, for example, it may be used in 3D displays. In 3D display, a large display pixel may be divided into a plurality of display regions, and each display region may display object information from different angles. When each display region is equipped with a microlens, 3D display can be achieved. For 3D display, the greater the number of divided display regions, the better the effect of 3D display. However, the greater the number of divided display regions, the narrower the pixel layout space, and the higher the requirements for process and equipment capabilities. In layout design, the shape of the pattern of each layer needs to be reasonably designed within a limited layout space to ensure signal transmission, reduce process requirements, and improve product yield.

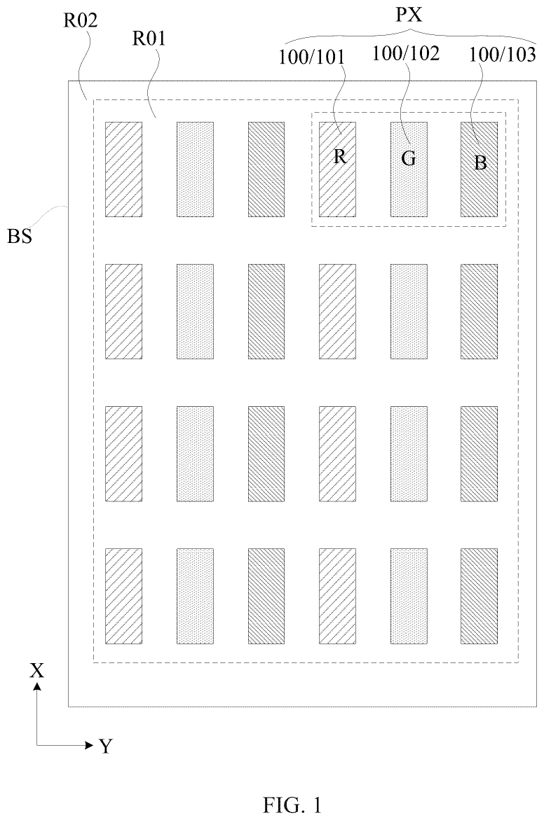

Exemplarily, each pixel currently includes four sub-pixels (red sub-pixel R, green sub-pixel G, blue sub-pixel B and white sub-pixel W) or three sub-pixels (red sub-pixel R, green sub-pixel G and blue sub-pixel B), and the layout space of each sub-pixel is relatively sufficient. For example, FIG. 1 is a schematic diagram of a planar structure of a pixel layout of a display substrate. As shown in FIG. 1, the display substrate includes a plurality of sub-pixels 100 on a base substrate, and the plurality of sub-pixels 100 are arranged in an array. As shown in FIG. 1, the plurality of sub-pixels 100 are arranged in an array along a first direction X and a second direction Y.

As shown in FIG. 1, the display substrate includes a plurality of pixels PX, and each pixel PX includes a plurality of sub-pixels 100. As shown in FIG. 1, the plurality of sub-pixels 100 include first sub-pixels 101, second sub-pixels 102, and third sub-pixels 103. As shown in FIG. 1, each pixel PX includes one first sub-pixel 101, one second sub-pixel 102, and one third sub-pixel 103. For example, the first sub-pixel 101, the second sub-pixel 102, and the third sub-pixel 103 have different light-emitting colors. For example, the first sub-pixel 101 may be a red sub-pixel (R), the second sub-pixel 102 may be a green sub-pixel (G), and the third sub-pixel 103 may be a blue sub-pixel (B). For example, as shown in FIG. 1, the sub-pixels in the same column are sub-pixels that emit light of the same color. In the same row of sub-pixels, a plurality of pixels PX are arranged sequentially, with the first direction X as a column direction and the second direction Y as a row direction for illustration.

For example, in the structure shown in FIG. 1, the base substrate BS includes a display region R01 and a peripheral region R02 on at least one side of the display region R01. FIG. 1 takes the peripheral region R02 surrounding the four sides of the display region R01 as an example for illustration, and the plurality of sub-pixels 100 are in the display region R01.

The inventor(s) of the present disclosure has noticed that for the design of ultra-high-resolution display panels, the space occupied by each sub-pixel may be divided into 11 display units, but is not limited to 11 display units. The greater the number of display units, the better the display effect of the panel, that is, within the same space range as the current space occupied by one sub-pixel, the space of one sub-pixel is divided into 11 display units, and each display unit is driven independently, which is equivalent to that original 3 sub-pixels are increased to 33 display units. On this basis, as more display units are designed, in order to improve the yield of the display panel, it is necessary to minimize the density of the patterns of each layer during layout design. For example, the width of different parts of the signal line can be designed such that the main body part is wider to reduce the load on the signal line, and the waisted part is narrowed to increase the gap between the signal line and adjacent structures, thereby reducing the risk of defects during the manufacturing process.

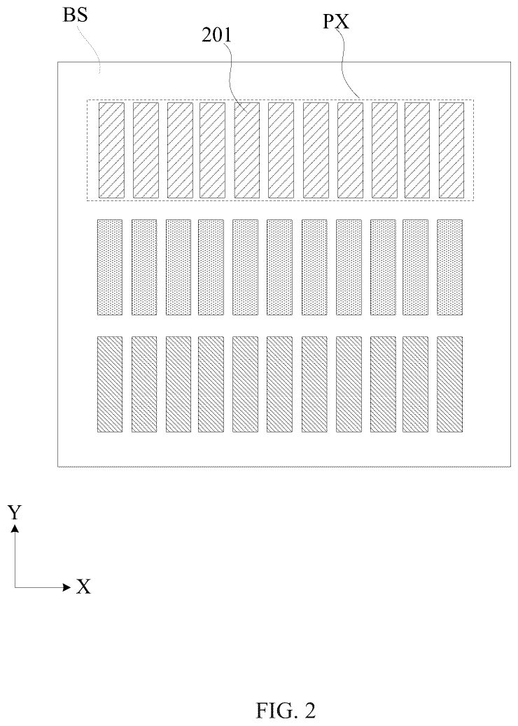

For example, FIG. 2 is a schematic diagram of a pixel layout of a display substrate provided by at least one embodiment of the present disclosure. FIG. 2 shows one pixel PX corresponding to FIG. 1, that is, corresponding to 3 sub-pixels, which correspond to sub-pixels of three different colors. Of course, the embodiments of the present disclosure are not limited to this. One pixel PX may also correspond to four sub-pixels, and the four sub-pixels correspond to sub-pixels of four different colors. As shown in FIG. 2, the space corresponding to one pixel PX in FIG. 1 is designed to form 33 display units 201, and each display unit 201 is driven independently.

For example, a plurality of display units 201 included in each sub-pixel may be independent display units 201 and be controlled independently, and different gray-scale images can be input to the sub-pixels of the same color. For 3D display, multi-gray-scale drive rendering is used to realize naked-eye 3D display with super multi-viewpoints. For example, FIG. 2 schematically shows that each pixel PX includes 11 display units 201, but the embodiments of the present disclosure are not limited thereto. The number of display units included in each sub-pixel may be determined according to the resolution required by the actual needs of the final display device that is formed.

For example, the layout of the display units shown in FIG. 2 refers to the arrangement positions of light-emitting regions of light-emitting elements 200b in the display units 201. The light-emitting region of the light-emitting element 200b is an effective light-emitting region. For example, the position of the light-emitting element 200b may correspond to the opening region of the pixel definition layer that defines the plurality of display units 201.

For example, at least one embodiment of the present disclosure provides a display substrate, the display substrate includes a base substrate, a plurality of sub-pixels, and a plurality of signal lines. The plurality of sub-pixels are arranged in an array along a first direction and a second direction that intersect each other on the base substrate, and include a plurality of pixel circuits. Each sub-pixel includes a plurality of display units, and each display unit is independently driven by a corresponding pixel circuit, adjacent display units form a pixel unit group, for example, two adjacent display units form a pixel unit group. At least part of the signal line extends along the second direction, two display units included in at least one pixel unit group are connected to the same signal line. In the second direction, at least one signal line includes a first connection portion and a second connection portion, and in the first direction, the width of the first connection portion is less than the width of the second connection portion. The embodiments of the present disclosure improve the effect of 3D display by designing more display units in the space corresponding to one sub-pixel of the display substrate, and in order to improve the yield of the display substrate, the widths of the first connection portion and the second connection portion of the signal line are designed so that the width of the first connection portion is less than the width of the second connection portion to reduce the load on the signal line. Additionally, by increasing the gap between the signal line and adjacent structures at the position corresponding to the first connection portion, the risk of defects during the manufacturing process can be reduced.

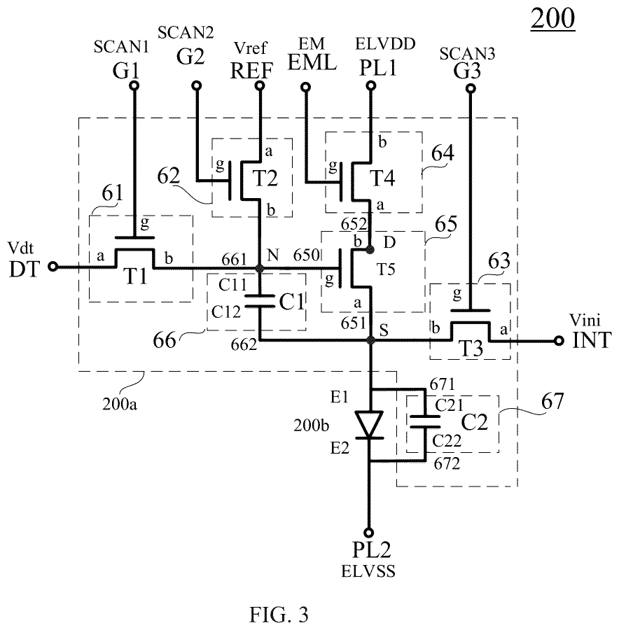

First, the circuit diagram of the display unit provided by the embodiments of the present disclosure will be described with reference to FIG. 3 to FIG. 11 below. It should be noted that, in the embodiments of the present disclosure, each circuit diagram is illustrated with 5T2C (that is, five transistors and two capacitors) as an example. Of course, the embodiments of the present disclosure are not limited to this. The circuit diagram may also be a structure including other numbers of transistors and capacitors, such as a 3T1C structure, a 7T2C structure, a 6T1C structure, a 6T2C structure, an 8T1C structure or a 9T2C structure, and the embodiments of the present disclosure are not limited to this.

For example, FIG. 3 is a circuit diagram of a display unit in a display substrate provided by at least one embodiment of the present disclosure. FIG. 3 shows a circuit diagram of a display unit. As shown in FIG. 3, the display unit 201 includes a pixel circuit 200a and a light-emitting element 200b. The light-emitting element 200b is electrically connected to the pixel circuit 200a, and the pixel circuit 200a is configured to drive the light-emitting element 200b.

For example, as shown in FIG. 3, the pixel circuit 200a includes a driving circuit 65, a light-emitting control circuit 64, a data writing circuit 61, a first reset circuit 62, a second reset circuit 63, a first storage circuit 66, and a second storage circuit 67.

For example, as shown in FIG. 3, the driving circuit 65 includes a control terminal 650, a first terminal 651 and a second terminal 652. The first terminal 651 of the driving circuit 65 is electrically connected to a first electrode E1 of the light-emitting element 200b.

For example, as shown in FIG. 3, the light-emitting control circuit 64 is electrically connected to the second terminal 652 of the driving circuit 65 and is configured to transmit a first power supply voltage ELVDD to the second terminal 652 of the driving circuit 65 in response to a light-emitting control signal.

For example, as shown in FIG. 3, the data writing circuit 61 is electrically connected to the control terminal 650 of the driving circuit 65 and is configured to write a data signal Vdt to the control terminal 650 of the driving circuit 65 in response to a first scanning signal SCAN1.

For example, as shown in FIG. 3, the first reset circuit 62 is electrically connected to the control terminal 650 of the driving circuit 65 and is configured to transmit a reference voltage Vref to the control terminal 650 of the driving circuit 65 in response to a second scanning signal SCAN2.

For example, as shown in FIG. 3, the second reset circuit 63 is electrically connected to the first electrode E1 of the light-emitting element 200b, and is configured to transmit an initialization voltage Vini to the first electrode E1 of the light-emitting element 200b in response to a third scanning signal SCAN3.

For example, as shown in FIG. 3, the first storage circuit 66 has a first terminal 661 and a second terminal 662. The first terminal 661 of the first storage circuit 66 is electrically connected to the control terminal 650 of the driving circuit 65, and the second terminal 662 of the first storage circuit 66 is electrically connected to the first terminal 651 of the driving circuit 65. The first storage circuit 66 is configured to store the data signal Vdt.

For example, as shown in FIG. 3, the second storage circuit 67 has a first terminal 671 and a second terminal 672. The first terminal 671 of the second storage circuit 67 is electrically connected to the first electrode E1 of the light-emitting element 200b, and the second terminal 672 of the second storage circuit 67 is electrically connected to a second electrode E2 of the light-emitting element 200b.

For example, as shown in FIG. 3, the display substrate further includes an initialization signal line INT, a reference voltage signal line REF, and a first power supply voltage signal line PL1. The initialization signal line INT is configured to provide the initialization voltage Vini to the pixel circuit 200a, the reference voltage signal line REF is configured to provide the reference voltage Vref to the pixel circuit 200a, and the first power supply voltage signal line PL1 is configured to provide the first power supply voltage ELVDD to the pixel circuit 200a.

For example, as shown in FIG. 3, the display substrate further includes a second power supply voltage signal line PL2, and the second power supply voltage signal line PL2 is configured to provide a second power supply voltage EL VSS to the display unit 201.

For example, the first power supply voltage ELVDD is a fixed voltage, that is, a DC signal. For example, the second power supply voltage ELVSS is also a fixed voltage, that is, a DC signal.

For example, the initialization voltage Vini is between the first power supply voltage ELVDD and the second power supply voltage ELVSS, but the embodiments of the present disclosure are not limited thereto. For example, the initialization voltage Vini is a fixed voltage, that is, the initialization voltage Vini is also a DC signal.

For example, the reference voltage Vref is between the first power supply voltage ELVDD and the second power supply voltage ELVSS, but the embodiments of the present disclosure are not limited thereto. For example, the reference voltage Vref is a fixed voltage, that is, the reference voltage Vref is a DC signal.

For example, in some embodiments of the present disclosure, the first power supply voltage ELVDD is approximately 10V, the second power supply voltage ELVSS may be the ground voltage, the second power supply voltage ELVSS is approximately 0V, the reference voltage Vref is approximately 2V, and the initialization voltage Vini may be between −4V and −5V. Of course, the above values are only examples and may be set according to actual needs.

For example, as shown in FIG. 3, the pixel circuit 200a includes a driving transistor T5, a light-emitting control transistor T4, a data writing transistor T1, a reset transistor T2, a reset transistor T3, a first capacitor C1, and a second capacitor C2.

For example, as shown in FIG. 3, a first electrode T5a of the driving transistor T5 is electrically connected to the first electrode E1 of the light-emitting element 200b.

For example, as shown in FIG. 3, the light-emitting control transistor T4 is electrically connected to a second electrode of the driving transistor T5, and is configured to transmit the first power supply voltage ELVDD to the second electrode of the driving transistor T5 in response to the light-emitting control signal.

For example, as shown in FIG. 3, the data writing transistor T1 is electrically connected to a gate electrode of the driving transistor T5, and is configured to write the data signal Vdt to the gate electrode of the driving transistor T5 in response to the first scanning signal SCAN1.

For example, as shown in FIG. 3, the reset transistor T2 is electrically connected to the gate electrode of the driving transistor T5, and is configured to transmit the reference voltage Vref to the gate electrode of the driving transistor T5 in response to the second scanning signal SCAN2.

For example, as shown in FIG. 3, the reset transistor T3 is electrically connected to the first electrode E1 of the light-emitting element 200b, and is configured to transmit the initialization voltage Vini to the first electrode E1 of the light-emitting element 200b in response to the third scanning signal SCAN3.

For example, as shown in FIG. 3, a first electrode plate C11 of the first capacitor C1 is electrically connected to the gate electrode T5g of the driving transistor T5, a second electrode plate C12 of the first capacitor C1 is electrically connected to the first electrode T5a of the driving transistor T5, and the first capacitor C1 is configured to store the data signal Vdt.

For example, as shown in FIG. 3, a first electrode plate C21 of the second capacitor C2 is electrically connected to the first electrode E1 of the light-emitting element 200b, and a second electrode plate C22 of the second capacitor C2 is electrically connected to the second electrode E2 of the light-emitting element 200b. For example, the first electrode E1 of the light-emitting element 200b may be served as the first electrode plate C21, and the second electrode E2 of the light-emitting element 200b may be served as the second electrode plate C22.

As shown in FIG. 3, the second power supply voltage signal line PL2 is electrically connected to the second electrode E2 of the light-emitting element 200b.

As shown in FIG. 3, the display substrate 200 further includes a first gate line G1, a second gate line G2, and a third gate line G3. The first gate line G1 is configured to provide the first scanning signal SCAN1 to the pixel circuit 200a, the second gate line G2 is configured to provide the second scanning signal SCAN2 to the pixel circuit 200a, and the third gate line G3 is configured to provide the third scanning signal SCAN3 to the pixel circuit 200a.

As shown in FIG. 3, the display substrate further includes a light-emitting control line EML, and the light-emitting control line EML is configured to provide a light-emitting control signal EM to the pixel circuit 200a.

As shown in FIG. 3, the display substrate 200 further includes a data line DT, and the data line DT is configured to provide the data signal Vdt to the pixel circuit 200a. For example, sub-pixels can display different grayscales according to different data signals.

As shown in FIG. 3, the driving transistor T5 is electrically connected to the light-emitting element 200b, and outputs a driving current to drive the light-emitting element 200b to emit light under the control of signals such as the first scanning signal SCAN1, the second scanning signal SCAN2, the third scanning signal SCAN3, the light-emitting control signal EM, the data signal Vdt, the first power supply voltage ELVDD, and the second power supply voltage ELVSS.

For example, the light-emitting element 200b includes an organic light-emitting diode (OLED), but the embodiments of the present disclosure are not limited thereto. For example, the light-emitting element 200b emits red light, green light, blue light, or white light, etc. under the driving of its corresponding pixel circuit 200a.

For example, as shown in FIG. 3, the gate electrode of the driving transistor T5, the first electrode plate C11 of the first capacitor C1, a second electrode T1b of the data writing transistor T1, and a second electrode T2b of the reset transistor T2 are all connected to each other, that is, connected to a node N.

For example, as shown in FIG. 3, the second electrode T5b of the driving transistor T5 and a first electrode T4a of the light-emitting control transistor T4 are connected to each other, that is, both are connected to a node D.

For example, as shown in FIG. 3, the first electrode T5a of the driving transistor T5, the second electrode plate C12 of the first capacitor C1, a second electrode of the reset transistor T3, the first electrode E1 of the light-emitting element 200b, and the first electrode plate C21 of the second capacitor C2 are all connected to each other and connected to a node S. There are many components connected to the node S, which easily generates leakage current, making the voltage of the node S unstable. Setting the second capacitor C2 can make the voltage of the node S more stable, thereby making the driving current more accurate.

For example, as shown in FIG. 3, a first electrode T1a of the data writing transistor T1 is connected to the data line DT, and a gate electrode T1g of the data writing transistor T1 is connected to the first gate line G1.

For example, as shown in FIG. 3, a first electrode T2a of the reset transistor T2 is connected to the reference voltage signal line REF, and a gate electrode T2g of the reset transistor T2 is connected to the second gate line G2.

For example, as shown in FIG. 3, a first electrode T3a of the reset transistor T3 is connected to the initialization signal line INT, and a gate electrode T3g of the reset transistor T3 is connected to the third gate line G3.

For example, as shown in FIG. 3, a second electrode T4b of the light-emitting control transistor T4 is connected to the first power supply voltage signal line PL1, and a gate electrode T4g of the light-emitting control transistor T4 is connected to the light-emitting control line EML.

For example, as shown in FIG. 3, the second electrode plate C22 of the second capacitor C2 is connected to the second power supply voltage signal line PL2.

For example, as shown in FIG. 3, the second electrode E2 of the light-emitting element 200b is connected to the second power supply voltage signal line PL2.

For example, as shown in FIG. 3, the driving circuit 65 includes the driving transistor T5, the gate electrode T5g of the driving transistor T5 may correspond to the control terminal of the driving circuit 65, and the first electrode T5a and the second electrode T5b of the driving transistor T5 may respectively correspond to the first terminal and the second terminal of the driving circuit 65.

For example, as shown in FIG. 3, the light-emitting control circuit 64 includes the light-emitting control transistor T4, the gate electrode T4g of the light-emitting control transistor T4 may correspond to the control terminal of the light-emitting control circuit 64, and the first electrode T4a and the second electrode T4b of the light-emitting control transistor T4 may respectively correspond to the first terminal and the second terminal of the light-emitting control circuit 64.

For example, as shown in FIG. 3, the data writing circuit 61 includes the data writing transistor T1, the gate electrode T1g of the data writing transistor T1 may correspond to the control terminal of the data writing circuit 61, and the first electrode T1a and the second electrode T1b of the data writing transistor T1 may respectively correspond to the first terminal and the second terminal of the data writing circuit 61.

For example, as shown in FIG. 3, the first reset circuit 62 includes the reset transistor T2, the gate electrode T2g of the reset transistor T2 may correspond to the control terminal of the first reset circuit 62, and the first electrode T2a and the second electrode T2b of the reset transistor T2 may respectively correspond to the first terminal and the second terminal of the first reset circuit 62.

For example, as shown in FIG. 3, the second reset circuit 63 includes the reset transistor T3, the gate electrode T3g of the reset transistor T3 may correspond to the control terminal of the second reset circuit 63, and the first electrode T3a and the second electrode T3b of the reset transistor T3 may respectively correspond to the first terminal and the second terminal of the second reset circuit 63.

For example, as shown in FIG. 3, the first terminal 661 and the second terminal 662 of the first storage circuit 66 may respectively correspond to the first electrode plate C11 and the second electrode plate C12 of the first capacitor C1.

For example, as shown in FIG. 3, the first terminal 671 and the second terminal 672 of the second storage circuit 67 may respectively correspond to the first electrode plate C21 and the second electrode plate C22 of the second capacitor C2.

For each transistor, in FIG. 3, “g” represents a gate electrode of a transistor, “a” represents a first electrode of the transistor, and “b” represents a second electrode of the transistor.

It should be noted that all the transistors adopted in the embodiments of the present disclosure may be TFTs, field-effect transistors (FETs) or other switching elements having the same characteristics. A source electrode and a drain electrode of the transistor adopted herein may be symmetrical in structure, so the source electrode and the drain electrode of the transistor may have no difference in structure. In the embodiments of the present disclosure, in order to distinguish two electrodes except the gate electrode of the transistor, one electrode is directly described as the first electrode and the other electrode is directly described as the second electrode, so the first electrode and the second electrode of all or part of the transistors in the embodiments of the present disclosure can be exchanged as required. For example, the first electrode of the transistor in the embodiments of the present disclosure may be the source electrode and the second electrode may be the drain electrode; or the first electrode of the transistor may be the drain electrode and the second electrode may be the source electrode.

In addition, the transistors may be divided into N-type transistors and P-type transistors according to characteristics of the transistors. The embodiments of the present disclosure are illustrated by an example in which the transistors are all N-type transistors (N-MOS). Based on the description and teaching of this implementation in the present disclosure, those skilled in the art can easily think of adopting P-type transistors for at least some of the transistors in the pixel circuit structure of the embodiments of the present disclosure without creative work, that is, adopting P-type transistors or a combination of N-type transistors and P-type transistors, therefore, these implementations are also within the protection scope of the present disclosure.

The embodiments of the present disclosure are illustrated by taking the above-mentioned five transistors being N-type transistors as an example.

For example, the pixel circuit in the display substrate shown in FIG. 3 is an internal compensation circuit with a 5T2C structure. The gate electrode (node N), second electrode (node D), and first electrode (node S) of the driving transistor T5 all have floating time, so it is necessary to avoid the effects of noise on at least one of the nodes N, D, and S, in order to prevent display defects (such as Mura) in the display substrate and thus improve the display effect. The embodiments of the present disclosure take a pixel circuit with a 5T2C structure as an example for description, but the embodiments of the disclosure are not limited thereto, and the structure of the pixel circuit may be determined as needed. For example, in some embodiments, the light-emitting control transistor T4 may not be provided, and only four transistors and two capacitors may be provided.

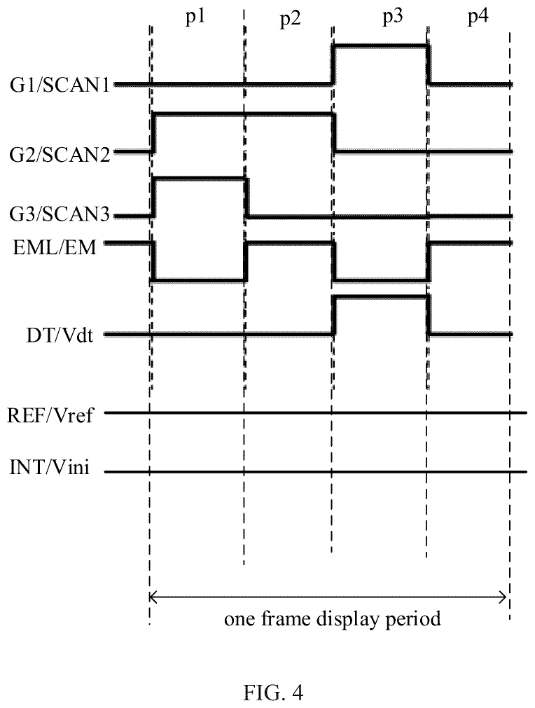

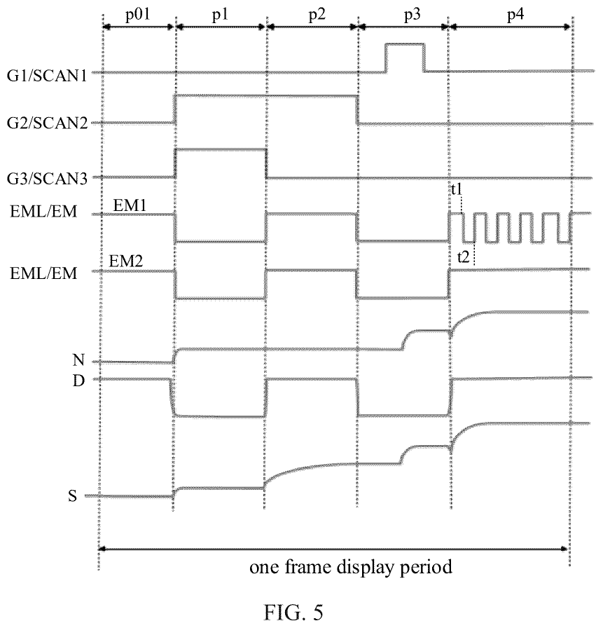

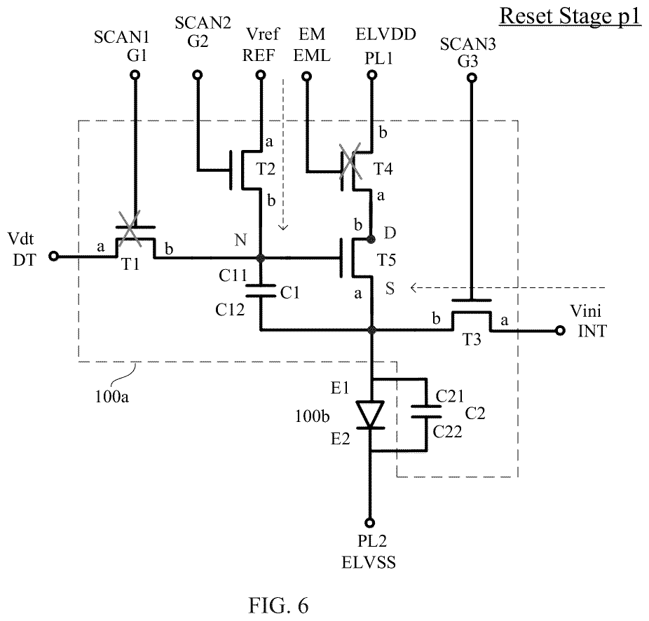

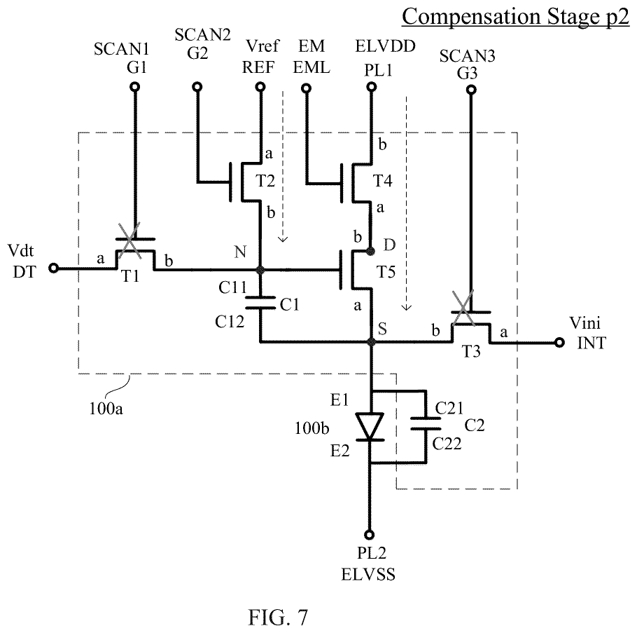

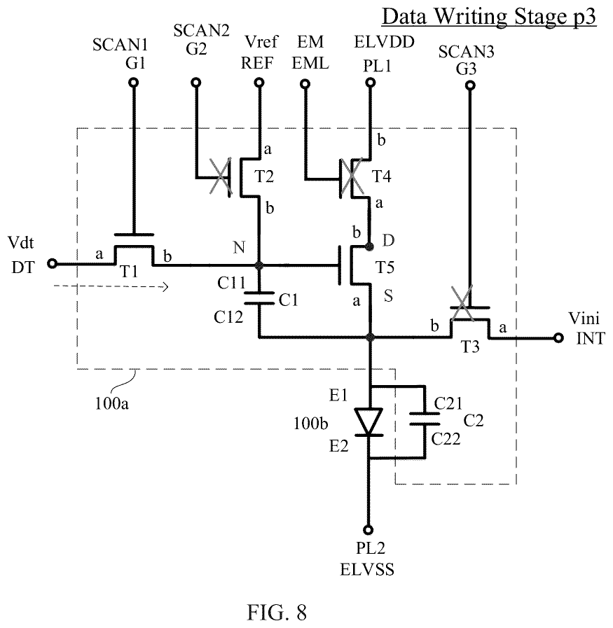

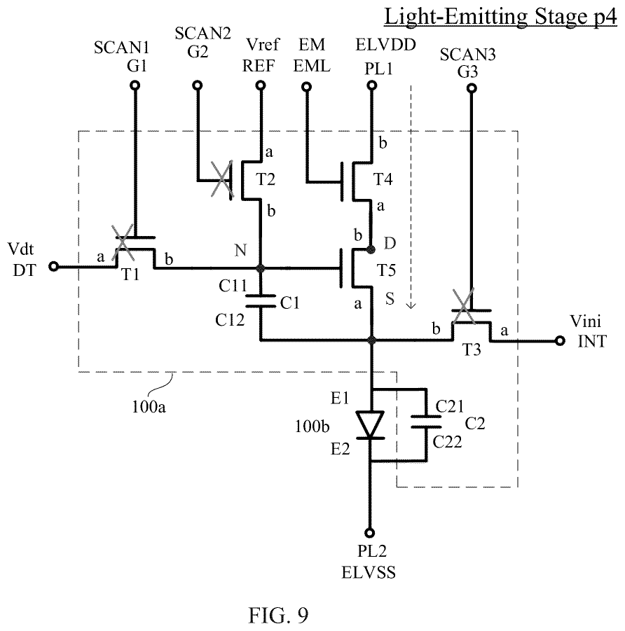

FIG. 4 is a timing signal diagram of a display unit of a display substrate provided by embodiments of the present disclosure; FIG. 5 is a timing signal diagram of a display unit of a display substrate provided by embodiments of the present disclosure; FIG. 6 is a schematic diagram of a transistor turning-on/off during a reset stage of a display unit of a display substrate provided by embodiments of the present disclosure; FIG. 7 is a schematic diagram of a transistor turning-on/off during a compensation stage of a display unit of a display substrate provided by embodiments of the present disclosure; FIG. 8 is a schematic diagram of a transistor turning-on/off during a data writing stage of a display unit of a display substrate provided by embodiments of the present disclosure; and FIG. 9 is a schematic diagram of a transistor turning-on/off during a light-emitting stage of a display unit of a display substrate provided by embodiments of the present disclosure.

For example, as shown in FIG. 4 to FIG. 9, in a driving method of a display substrate provided by embodiments of the present disclosure, within one frame display period, the driving method includes a reset stage p1, a compensation stage p2, a data writing stage p3, and a light-emitting stage p4.

For example, as shown in FIG. 4 and FIG. 5, the first scanning signal SCAN1 is at a high level during the data writing stage p3, and at a low level during the reset stage p1, the compensation stage p2, and the light-emitting stage p4.

For example, as shown in FIG. 4 and FIG. 5, the second scanning signal SCAN2 is at a high level during the reset stage p1 and the compensation stage p2, and at a low level during the data writing stage p3 and the light-emitting stage p4.

For example, as shown in FIG. 4 and FIG. 5, the third scanning signal SCAN3 is at a high level during the reset stage p1, and at a low level during the compensation stage p2, the data writing stage p3, and the light-emitting stage p4.

For example, as shown in FIG. 4, the light-emitting control signal EM is at a high level during the compensation stage p2 and the light-emitting stage p4, and at a low level during the reset stage p1 and the data writing stage p3. As shown in FIG. 4, FIG. 5 and FIG. 6, during the reset stage p1, the second scanning signal SCAN2 is input, the first reset circuit 62 (reset transistor T2) is turned on, and the reference voltage Vref is transmitted to the control terminal 650 of the driving circuit 65 (driving transistor T5) through the first reset circuit 62, to reset the control terminal 650 of the driving circuit 65; and the third scanning signal SCAN3 is input, the second reset circuit 63 (reset transistor T3) id turned on, the initialization voltage Vini is transmitted to the first electrode E1 of the light-emitting element 200b through the second reset circuit 63, to reset the first electrode E1 of the light-emitting element 200b.

For example, as shown in FIG. 6, the reset transistor T2 and the reset transistor T3 are turned on, and the data writing transistor T1 and the light-emitting control transistor T4 are turned off, so that the gate electrode (node N) of the driving transistor T5 and the first electrode E1 (node S) of the light-emitting element 200b are respectively reset to the reference voltage Vref and the initialization voltage Vini. In this case, the voltage VN of the node N is the reference voltage Vref, and the voltage Vs of the node S is the initialization voltage Vini.

For example, in the driving method of the display substrate, during the reset stage p1, the light-emitting control circuit 64 (light-emitting control transistor T4) is turned off, so that the node S is sufficiently reset.

For example, as shown in FIG. 6, during the reset stage p1, the light-emitting control transistor T4 is turned off, so that the node S is sufficiently reset. For example, the voltage drop of the initialization signal line INT is small.

For example, as shown in FIG. 4, FIG. 5 and FIG. 7, during the compensation stage p2, the second scanning signal SCAN2 and the light-emitting control signal EM are input, the first reset circuit 62 (reset transistor T2) is kept on, and the light-emitting control circuit 64 (light-emitting control transistor T4) and the driving circuit 65 (driving transistor T5) are turned on, so that the first electrode plate C21 (node S) of the second capacitor C2 is charged by the first power supply voltage ELVDD to compensate the driving circuit 65.

For example, as shown in FIG. 7, during the compensation stage p2, the reset transistor T2 and the light-emitting control transistor T4 are turned on, the data writing transistor T1 is turned off, and the reset transistor T3 is turned off.

For example, as shown in FIG. 4, FIG. 5 and FIG. 7, because the reset transistor T2 continues to be in the turning-on state, the voltage VN of the node N is maintained at the reference voltage Vref. At the same time, because the light-emitting control transistor T4 is turned on, the first power supply voltage ELVDD charges the node S through the driving the transistor T5, and when the gate-source voltage difference Vgs of the driving transistor T5 is equal to a threshold voltage Vth of the driving transistor T5, the driving transistor T5 is turned off and charging ends. In this case, the voltage of node S is Vref-Vth.

For example, the voltage of the node N is VN, the voltage of the node S is VS, the gate-source voltage difference of the driving transistor T5 is Vgs, the threshold voltage of the driving transistor T5 is Vth; during the compensation stage p2, VN=Vref, the first power supply voltage ELVDD on the first power supply voltage signal line PL1 charges the second capacitor C2 until VS=Vref−Vth. In this case, the gate-source voltage difference of the driving transistor T5 is Vgs=VN−Vs=Vref−(Vref−Vth)=Vth, and Vref is set to Vref>Vth+Vini, which can turn on the driving transistor T5 and complete the compensation charging.

For example, in the driving method of the display substrate, during the compensation stage p2, the reference voltage Vref is greater than the sum of the threshold voltage of the driving circuit 65 (threshold voltage Vth of the driving transistor T5) and the initialization voltage Vini, so as to turn on the driving transistor T5 and complete the compensation charging.

For example, compensation time is the turning-on time of the reset transistor T2 minus the turning-on time of the reset transistor T3. The pulse width may be used to debug the driving circuit to be turned on for a long time to complete long-time compensation.

For example, when setting the reference voltage Vref, ensure that Vs<V0 according to the specification of the threshold voltage Vth of the driving transistor T5, and V0 is the turning-on voltage of the light-emitting element 200b. That is, Vref−Vth<V0, Vref<V0+Vth, and Vref<V0 are sufficient.

For example, in the driving method of the display substrate, the reference voltage Vref is smaller than the turning-on voltage V0 of the light-emitting element 200b.

For example, as shown in FIG. 4, FIG. 5 and FIG. 8, during the data writing stage p3, the first scanning signal SCAN1 is input, the data writing circuit 61 (data writing transistor T1) is turned on, and the data signal Vdt is written into the control terminal 650 of the driving circuit 65.

For example, as shown in FIG. 8, during the data writing stage p3, the data writing transistor T1 is turned on, other transistors are turned off (the light-emitting control transistor T4 may also be turned on to compensate for mobility), and the data signal Vdt is written into the node N, that is, the node N jumps from the reference voltage Vref to the data signal Vdt; the voltage of the first electrode plate C11 of the first capacitor C1 generates a jump of Vdt−Vref, and the voltage of the second electrode plate C12 of the first capacitor C1 generates a corresponding jump under the bootstrap action. That is, the node S is coupled through capacitance, and the voltage on the node S becomes VS=α(Vdt−Vref)+Vref−Vth. For example, in the above formula, α is a coefficient, for example, α=C1/(C1+C2), in this formula, C1 is the capacitance value of the first capacitor C1, and C2 is the capacitance value of the second capacitor C2. After the data writing stage p3 ends, the voltage of the node N is Vdt, and the voltage of the node S is α(Vdt−Vref)+Vref−Vth.

For example, in the driving method of the display substrate, during the data writing stage p3, the light-emitting control signal EM is also input, and the light-emitting control circuit 64 is turned on to compensate the driving circuit 65, to compensate for the mobility.

For example, as shown in FIG. 4, FIG. 5, and FIG. 9, during the light-emitting stage p4, the light-emitting control signal EM is input, and the light-emitting control circuit 64 (light-emitting control transistor T4) and the driving circuit 65 are turned on to generate a driving current to drive the light-emitting element 200b to emit light. The light-emitting control transistor T4 is turned on to provide the first power supply voltage ELVDD to the driving transistor T5.

For example, as shown in FIG. 9, during the light-emitting stage p4, the light-emitting control transistor T4 is turned on, and the data writing transistor T1, the reset transistor T2, and the reset transistor T3 are turned off. In this case, the driving current I is:

I=K*[(1−α)*(Vdt−Vref)]2.

It can be seen from the above formula that the driving current is related to the data signal Vdt and the reference voltage Vref, and the influence of the threshold voltage Vth of the driving transistor T5 on the driving current is successfully eliminated. Therefore, the driving current may be prevented from being affected by the nonuniformity and drift of the threshold voltage, thereby effectively improving the uniformity of driving current. In addition, because the driving current is not related to the first power supply voltage ELVDD and the second power supply voltage ELVSS, the influence of the voltage drop of the first power supply voltage signal line PL1 and the second power supply voltage line PL2 on the driving current may be effectively avoided.

According to α=C1/(C1+C2), it is known that the larger the capacitance value of the second capacitor C2, the smaller the α, which results in more energy savings.

For example, the voltage drop of the light-emitting control transistor T4 affects the first power supply voltage ELVDD and the linear region of the light-emitting control transistor T4, setting that EM>ELVDD+Vth_em, where Vth_em is the threshold voltage of the light-emitting control transistor T4.

For example, in the driving method of the display substrate, in the light-emitting stage p4, the light-emitting control signal EM is greater than the sum of the first power supply voltage ELVDD and the threshold voltage Vth_em of the light-emitting control circuit 64.

For example, the cross-voltage of the light-emitting element 200b is high, and the first power supply voltage ELVDD needs to be large, resulting in a high voltage of the light-emitting control signal EM.

The driving method of the display substrate provided by the embodiments of the present disclosure is beneficial to improving the display effect.

For example, FIG. 5 also shows a reset stage p01 of a gate driver on array (GOA). As shown in FIG. 5, the reset stage p01 precedes the reset stage p1.

For example, FIG. 5 shows the light-emitting control signal EM. FIG. 5 shows two types of light-emitting control signals EM: a light-emitting control signal EM1 and a light-emitting control signal EM2. One of the light-emitting control signal EM1 and the light-emitting control signal EM2 may be selected and used.

For example, as shown in FIG. 5, the difference between the light-emitting control signal EM1 and the light-emitting control signal EM2 is that during the light-emitting stage p4, the voltage value of the light-emitting control signal EM1 changes periodically, while the voltage value of the light-emitting control signal EM2 does not change.

For example, as shown in FIG. 5, the light-emitting control signal EM1 achieves dimming by rapidly turning on and off the light-emitting control transistor T4, which may be referred to as pulse width modulation (PWM) dimming, which regulates the screen's brightness by adjusting the on and off time of the light, that is, the brightness of the sub-pixels remains constant, and only the illumination time of the sub-pixels varies.

For example, as shown in FIG. 5, in one cycle of the light-emitting control signal EM1, the ratio of the turning-on time t1 to the cycle t2 is the duty cycle.

For example, FIG. 4 shows the voltage waveform of the data signal Vdt, and FIG. 4 and FIG. 5 show the voltage waveform of the first scanning signal SCNA1, the voltage waveform of the second scanning signal SCNA2, the voltage waveform of the third scanning signal SCNA3, and the voltage waveform of the light-emitting control signal EM.

For example, FIG. 5 further shows the voltage waveform of the node N during various stages, the voltage waveform of the node D during various stages, and the voltage waveform of the node S during various stages.

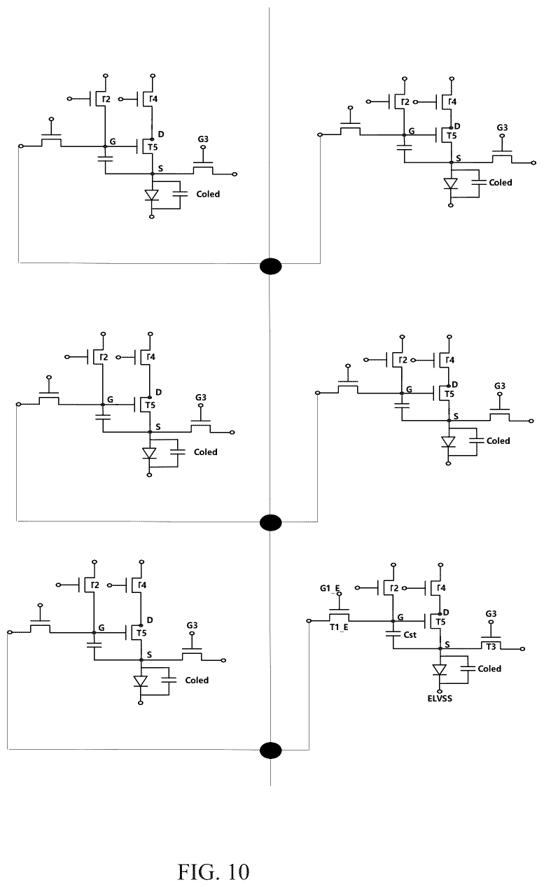

For example, FIG. 10 is a circuit diagram of a plurality of display units of a display substrate provided by at least one embodiment of the present disclosure. As shown in FIG. 10, display units in two adjacent columns are used as an example for illustration. In a first column, one display unit R11 corresponding to the red sub-pixel G, one display unit G11 corresponding to the green sub-pixel G, and one display unit B11 corresponding to the blue sub-pixel B are shown respectively; correspondingly, in a second column, one display unit R12 corresponding to the red sub-pixel R, one display unit G12 corresponding to the green sub-pixel G, and one display unit B12 corresponding to the blue sub-pixel B are shown respectively. The data writing transistor T1 in the display unit in the first column is represented by T1_O, and the first gate line is represented by G1_O. The data writing transistor T1 in the display unit in the second column is represented by T1_E, and the first gate line is represented by G1_E. The data writing transistor T1_O of the display unit in the first column and the data writing transistor T1_E of the display unit in the second column are connected to the same data line. For example, the display unit R11 and the display unit R12 are connected to the same position of the same data line, the display unit G11 and the display unit G12 are connected to the same position of the same data line, and the display unit B11 and the display unit B12 are connected to the same position of the same data line, which reduces the number of data lines to save space.

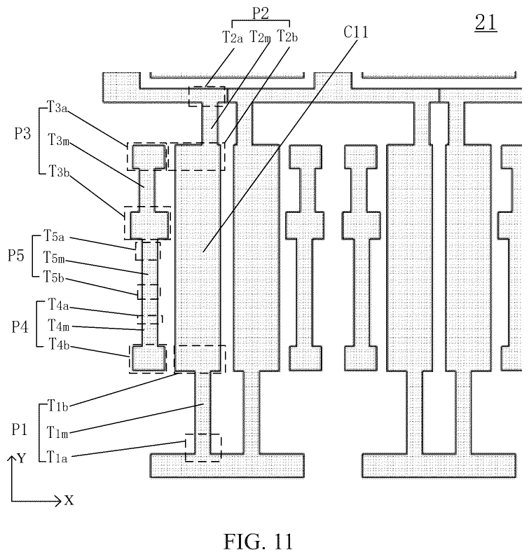

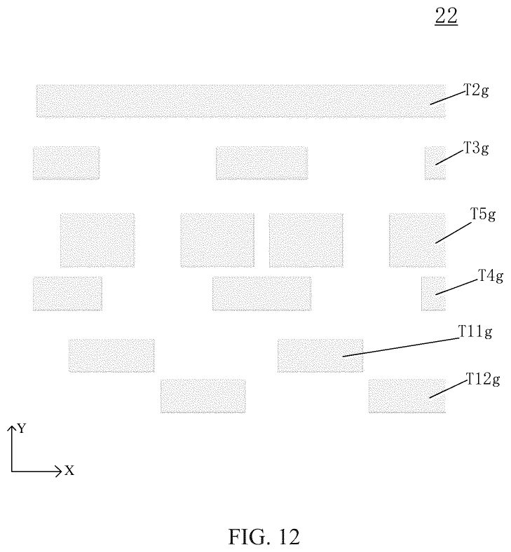

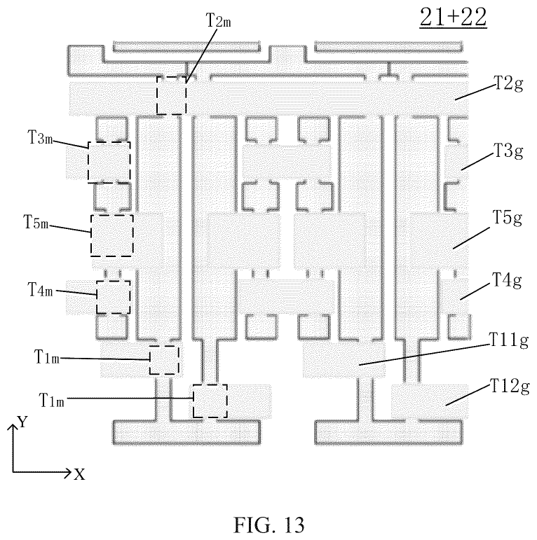

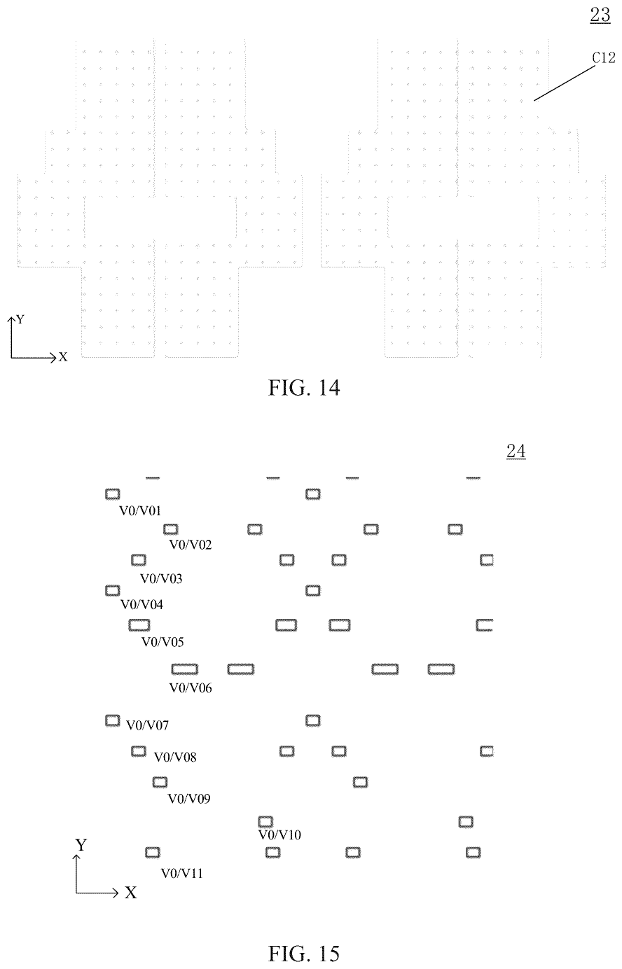

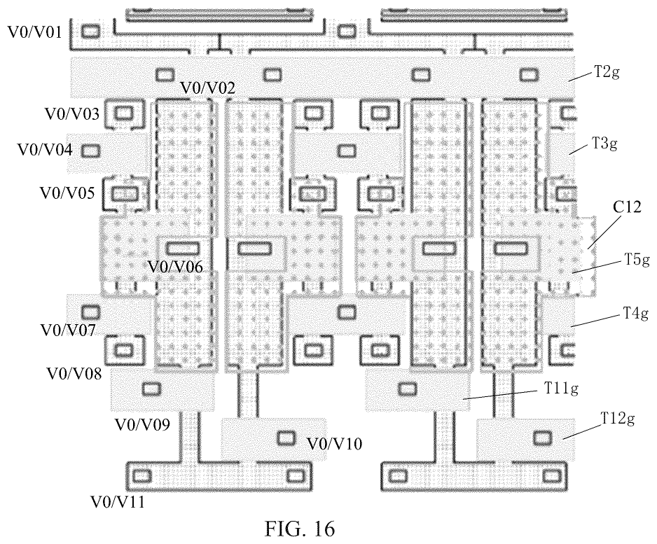

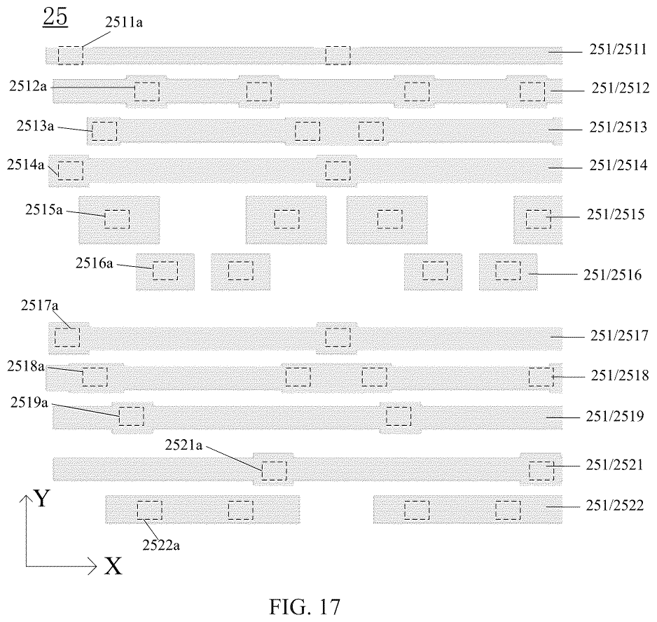

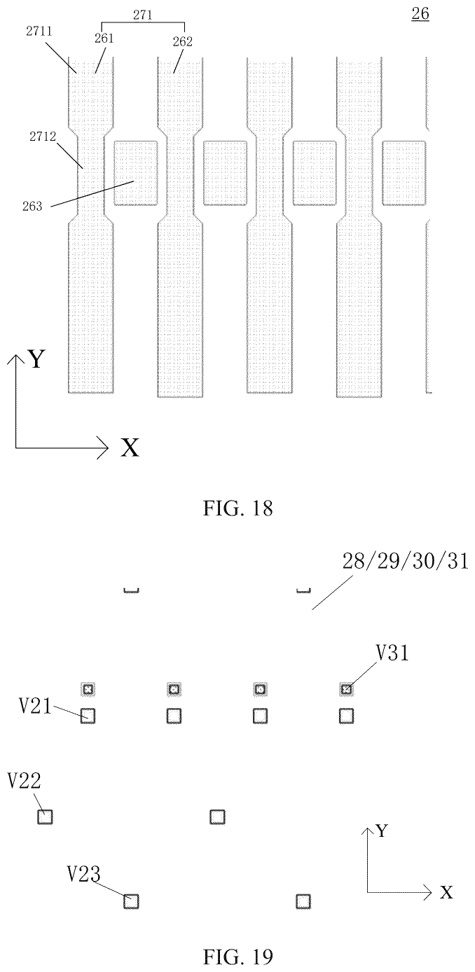

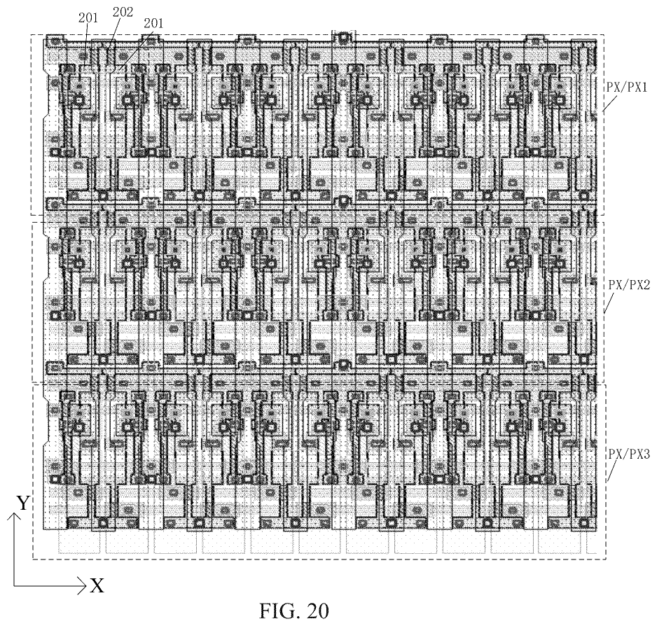

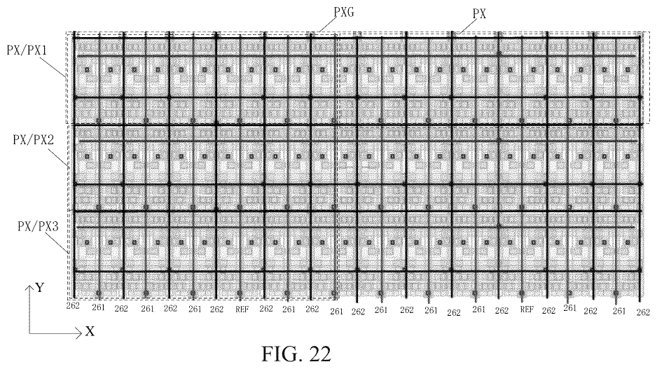

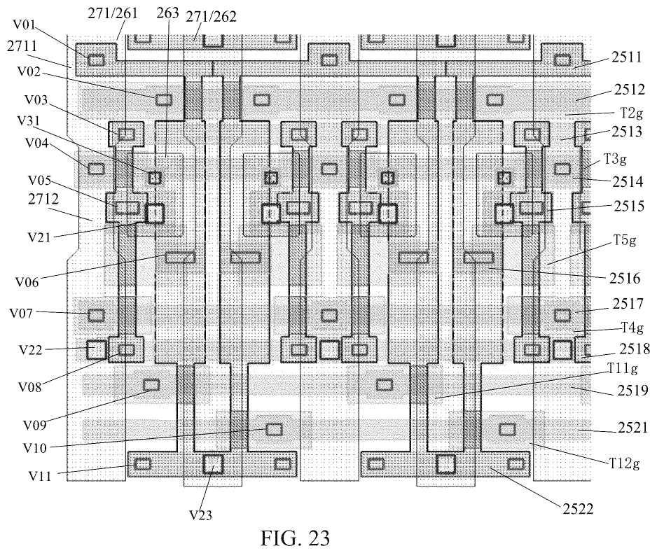

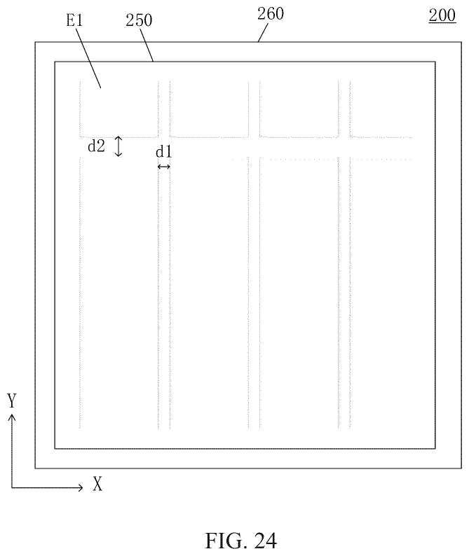

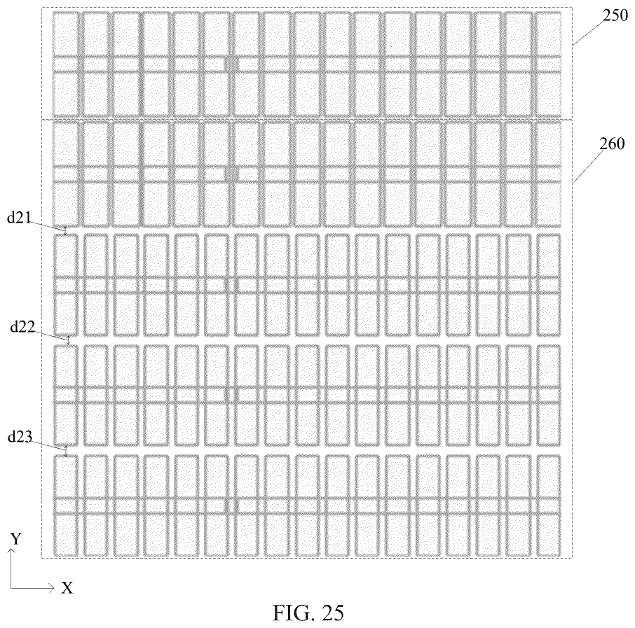

FIG. 11, FIG. 12, FIG. 14, FIG. 15, FIG. 17, FIG. 18, FIG. 19, FIG. 24 and FIG. 25 are single-layer diagrams in a display substrate provided by the embodiments of the present disclosure, and FIG. 13, FIG. 16, FIG. 20, FIG. 22, and FIG. 23 are stacked layers diagrams of a display substrate provided by the embodiments of the present disclosure.

It should be noted that the single-layer diagram or the stacked layers diagram is shown based on four display units, that is, the layer structures corresponding to the four display units are shown in each single-layer diagram or the stacked layers diagram.

For example, FIG. 11 is a schematic diagram of a planar structure of a semiconductor layer provided by at least one embodiment of the present disclosure. With reference to FIG. 3 and FIG. 11, the semiconductor layer 21 is a semiconductor layer 21 corresponding to four display units. The semiconductor layer 21 corresponding to each display unit includes a first active portion P1, a second active portion P2, a third active portion P3, a fourth active portion P4, and a fifth active portion P5. As shown in FIG. 11, each of the first active portion P1, the second active portion P2, the third active portion P3, the fourth active portion P4, and the fifth active portion P5 includes a channel, and a first electrode and a second electrode on both sides of the channel. As shown in FIG. 11, the first active portion P1 includes a channel T1m, the first electrode T1a, and the second electrode T1b of the data writing transistor T1; the second active portion P2 includes a channel T2m, the first electrode T2a, and the second electrode T2b of the reset transistor T2; the third active portion P3 includes a channel T3m, the first electrode T3a, and the second electrode T3b of the reset transistor T3; the fourth active portion P4 includes a channel T4m, the first electrode T4a, and the second electrode T4b of the light-emitting control transistor T4; and the fifth active portion P5 includes a channel T5m, the first electrode T5a, and the second electrode T5b of the driving transistor T5. The arrangement positions of the first active portion P1, the second active portion P2, the third active portion P3, the fourth active portion P4, and the fifth active portion P5 determine the arrangement positions of respective transistors.

For example, in the structure shown in FIG. 11, the semiconductor layer 21 further includes the first electrode plate C11 of the first capacitor C1, and the first electrode plate C11 is between the second electrode T2b of the reset transistor T2 and the first electrode T1a of the data writing transistor T1.

For example, as shown in FIG. 10, in the structure of the semiconductor layer corresponding to each display unit, the first active portion P1 and the second active portion P2 are in an integrated structure, that is, the channel T1m, the first electrode T1a and the second electrode T1b of the data writing transistor T1, and the channel T2m, the first electrode T2a, and the second electrode T2b of the reset transistor T2 are formed as an integrated structure. The third active portion P3, the fourth active portion P4, and the fifth active portion P5 are in an integrated structure, that is, the channel T3m, the first electrode T3a, and the second electrode T3b of the reset transistor T3, the channel T4m, the first transistor T4a, and the second transistor T4b of the light-emitting control transistor T4, and the channel T5m, the first transistor T5a, and the second transistor T5b of the driving transistor T5 are formed as an integrated structure.

For example, in the semiconductor layer 21 shown in FIG. 11, the semiconductor structures corresponding to two adjacent display units are axially symmetrical with respect to a straight line extending in the second direction Y and form one pixel unit group, that is, the semiconductor structures corresponding to two display units connected to the same signal line are axially symmetrical with respect to a straight line extending in the second direction Y and form one pixel unit group, and semiconductor layers corresponding to the two display units included in the pixel unit group are connected into an integrated structure.

For example, FIG. 12 is a schematic diagram of a planar structure of a first metal layer provided by at least one embodiment of the present disclosure. As shown in FIG. 12, the first metal layer 22 includes the gate electrode T2g of the first reset transistor T2, the gate electrode T3g of the second reset transistor T3, the gate electrode T5g of the driving transistor T5, the gate electrode T4g of the light-emitting control transistor T4, as well as the gate electrode T11g of the data writing transistor T1 included in one of adjacent display units and a gate electrode T12g of the data writing transistor T1 included in the other of the adjacent display units, which are arranged sequentially in the second direction Y.

For example, with reference to FIG. 2 and FIG. 12, the gate electrodes T2g of respective first reset transistors T2 corresponding to the display units 201 included in at least one pixel PX are in an integrated structure. The gate electrodes T3g of the second reset transistors T3 included in the display units 201 included in the same pixel PX are provided independently of each other, the gate electrodes T5g of the driving transistors T5 included in the display units 201 included in the same pixel PX are provided independently of each other, the gate electrodes T4g of the light-emitting control transistors T4 included in the display units 201 included in the same pixel PX are provided independently of each other, and the respective gate electrodes T11g and respective gate electrodes T12g of the data writing transistors T1 included in the display units 201 included in the same pixel PX are provided independently of each other.

For example, as shown in FIG. 12, the gate electrodes T2g of four reset transistors T2 corresponding to four display units are in an integrated structure, and the gate electrode T2g extends in the first direction X. The gate electrodes T11g of the data writing transistors T1 corresponding to the four display units are independent structures that are not connected to each other; the gate electrodes T3g of the reset transistors T3 corresponding to the four display units are independent structures that are not connected to each other; the gate electrodes T4g of the light-emitting control transistors T4 corresponding to the four display units are independent structures that are not connected to each other; and the gate electrodes T5g of the driving transistors T5 corresponding to the four display units are independent structures that are not connected to each other.

For example, as shown in FIG. 12, in the same pixel unit group, that is, for two adjacent display units 201, the gate electrode T11g of the data writing transistor T1 corresponding to one display unit 201 and the gate electrode T12g of the data writing transistor T1 corresponding to the other display unit 201 are arranged in a staggered manner; that is, in the two adjacent display units 201, the gate electrode T11g of the data writing transistor T1 corresponding to one display unit 201 and the gate electrode T12g of the data writing transistor T1 corresponding to the other display unit 201 do not have an overlapping portion in both the first direction X and the second direction Y.

For example, as shown in FIG. 12, the gate electrodes T11g of the data writing transistors T1 corresponding to the four display units are arranged in a staggered manner, that is, the gate electrodes T11g of the data writing transistors T1 corresponding to the four display units do not have an overlapping portion in both the first direction X and the second direction Y.

For example, FIG. 13 is a schematic diagram of a stacked layers structure including a semiconductor layer and a first metal layer provided by at least one embodiment of the present disclosure. With reference to FIG. 2, FIG. 3 and FIG. 13, orthographic projections of the gate electrode T11g of the data writing transistor T1, the gate T2g electrode of the reset transistor T2, the gate electrode T3g of the reset transistor T3, the gate electrode T4g of the light-emitting control transistor T4, and the gate electrode T5g of the driving transistor T5, corresponding to one display unit 201, on the base substrate BS respectively correspond to and overlap with orthographic projections of the channel T1m (on the left) of the corresponding data writing transistor T1, the channel T2m of the reset transistor T2, the channel T3m of the reset transistor T3, the channel T4m of the light-emitting control transistor T4, and the channel T5m of the driving transistor T5 on the base substrate BS. The orthographic projection of the gate electrode T12g of the data writing transistor T12 corresponding to a display unit adjacent to the one display unit on the base substrate BS overlaps with the orthographic projection of the channel T1m (on the right) of the corresponding data writing transistor T1 on the base substrate BS.

For example, FIG. 14 is a schematic diagram of a planar structure of a second metal layer provided by at least one embodiment of the present disclosure. As shown in FIG. 14, the second metal layer 23 includes a lower electrode plate C12 of the first capacitor C1, that is, FIG. 14 illustrates lower electrode plates C12 of first capacitors C1 corresponding to four display units. The lower electrode plates C12 of first capacitors C1 corresponding to two adjacent display units are axially symmetrical with respect to a straight line extending in the second direction Y.

For example, as shown in FIG. 14, the lower electrode plate C12 of the first capacitor C1 of each display unit includes a notch. In one pixel unit group, the notches of the lower electrode plates C12 of the first capacitors C1 corresponding to two adjacent display units are arranged oppositely to form a rectangular opening between the lower electrode plates C12 of two first capacitors C1.

For example, FIG. 15 is a schematic diagram of a planar structure of an interlayer insulation layer provided by at least one embodiment of the present disclosure. As shown in FIG. 15, the interlayer insulation layer 24 is on the second metal layer 23. The interlayer insulation layer 24 includes a plurality of via structures V0, and the plurality of via structures V0 include a first via structure V01, a second via structure V02, a third via structure V03, a fourth via structure V04, a fifth via structure V05, a sixth via structure V06, a seventh via structure V07, an eighth via structure V08, a ninth via structure V09, a tenth via structure V10, and an eleventh via structure V11.

For example, it can be seen from FIG. 15 that any two adjacent via structures VO in the first direction X or the second direction Y are spaced apart from each other. This staggered layout of vias not only ensures that different layers may be connected, but also increases the spacing between adjacent structures, thereby improving the yield of the display substrate.

It should be noted that the above-mentioned semiconductor layer 21, first metal layer 22, second metal layer 23, etc. are all referred as functional layers, and the second conductive layer mentioned later may also be referred as a functional layer. The first conductive layer is electrically connected to a corresponding functional layer through the above-mentioned via structures V0.

For example, FIG. 16 is schematic diagram of a stacked layers structure including a semiconductor layer, a first metal layer, a second metal layer, and an interlayer insulation layer provided by at least one embodiment of the present disclosure. As shown in FIG. 16, the ninth via structure V09 and the tenth via structure V10 are arranged in a staggered manner in both the first direction X and the second direction Y, that is, the spacing between the ninth via structure V09 and the tenth via structure V10 is enlarged in both the first direction X and the second direction Y, which can reduce the demand for process and improve the yield of the product.

For example, FIG. 17 is a schematic diagram of a planar structure of a first conductive layer provided by at least one embodiment of the present disclosure. As shown in FIG. 16 and FIG. 17, the first conductive layer 25 includes a plurality of conductive structures 251 arranged in the second direction Y. A conductive portion 251a included in each conductive structure 251 is electrically connected to a functional layer through the via structure V0. The adjacent conductive portions 251a in the second direction Y are spaced apart in the first direction X, that is, the via structures V0 connecting the adjacent conductive portions 251a in the second direction Y and corresponding functional layers are spaced apart in the first direction X, so that the via structures V0 adjacent in the second direction Y may be arranged in a staggered manner in the first direction X, thereby increasing the spacing between structures in the same layer.

For example, the above-mentioned functional layers include the semiconductor layer 21, the first metal layer 22 and the second conductive layer mentioned later, which are stacked on the base substrate BS. The embodiments of the present disclosure are not limited thereto. According to different layer structures of the display substrate, the functional layers may also include additional layer structures.

For example, as shown in FIG. 17, the conductive structure 251 includes a first conductive structure 2511, a second conductive structure 2512, a third conductive structure 2513, a fourth conductive structure 2514, a fifth conductive structure 2515, a sixth conductive structure 2516, a seventh conductive structure 2517, an eighth conductive structure 2518, a ninth conductive structure 2519, a tenth conductive structure 2521, and an eleventh conductive structure 2522, which are arranged sequentially in the second direction Y.

For example, as shown in FIG. 17, the conductive portion 251a includes a first conductive portion 2511a, a second conductive portion 2512a, a third conductive portion 2513a, a fourth conductive portion 2514a, a fifth conductive portion 2515a, a sixth conductive portion 2516a, a seventh conductive portion 2517a, an eighth conductive portion 2518a, a ninth conductive portion 2519a, a tenth conductive portion 2521a, and an eleventh conductive portion 2522a, which are respectively portions of the first conductive structure 2511, the second conductive structure 2512, the third conductive structure 2513, the fourth conductive structure 2514, the fifth conductive structure 2515, the sixth conductive structure 2516, the seventh conductive structure 2517, the eighth conductive structure 2518, the ninth conductive structure 2519, the tenth conductive structure 2521, and the eleventh conductive structure 2522, and serve as the portions that are connected with different layer structures. For example, as shown in FIG. 17, any two adjacent portions among the first conductive portion 2511a, the second conductive portion 2512a, the third conductive portion 2513a, the fourth conductive portion 2514a, the fifth conductive portion 2515a, the sixth conductive portion 2516a, the seventh conductive portion 2517a, the eighth conductive portion 2518a, the ninth conductive portion 2519a, the tenth conductive portion 2521a, and the eleventh conductive portion 2522a in the second direction Y are spaced apart in the first direction X, so that positions where different layer structures are connected are spaced apart in the first direction X.

For example, as shown in FIG. 3 and FIG. 17, the first conductive structure 2511 is the reference voltage signal line REF, the second conductive structure 2512 is the second gate line G2, the third conductive structure 2513 is the initialization signal line INT, the fourth conductive structure 2514 is the third gate line G3, the fifth conductive structure 2515 is the first electrode T3a of the reset transistor T3, the sixth conductive structure 2516 is the first electrode T5a of the driving transistor T5, the seventh conductive structure 2517 is the light-emitting control line EML, the eighth conductive structure 2518 is the first power supply voltage signal line ELVDD, the ninth conductive structure 2519 is the first gate line G1_O corresponding to one display unit in one pixel unit group, the tenth conductive structure 2521 is the first gate line G1_E corresponding to the other display unit in the one pixel unit group, and the eleventh conductive structure 2522 is a data line connection line that connects adjacent data lines mentioned later. For example, the reference voltage signal line REF, the initialization signal line INT, the second gate line G2, the third gate line G3, the light-emitting control line EML, the first power supply voltage signal line ELVDD, the first gate line G1_O and the first gate line G1_E each extend along the first direction X and are sequentially arranged in the second direction Y, the first direction X intersects the second direction Y. That is, the reference voltage signal line REF, the initialization signal line INT, the second gate line G2, the third gate line G3, the light-emitting control line EML, the first power supply voltage signal line ELVDD, the first gate line G1_O, and the first gate line G1_E each extend along their respective length directions. In the embodiments of the present disclosure, the extension of a component along its length direction includes the limitation that the size of the component in its length direction is greater than the size of the component in other directions. The arrangement positions of the reference voltage signal line REF, the initialization signal line INT, and the first power supply voltage signal line ELVDD determine the arrangement positions of the reset transistor T2, the reset transistor T3, and the light-emitting control transistor T4 in the layout diagram.

For example, in one example, one of two adjacent display units 201 in the first direction X is electrically connected to the ninth conductive structure 2519, the other of the two adjacent display units 201 is electrically connected to the tenth conductive structure 2521; and in the second direction Y, the spacing between the ninth conductive structure 2519 and the tenth conductive structure 2521 is greater than the spacing between the ninth conductive structure 2519 and the eighth conductive structure 2518, and is greater than the spacing between the tenth conductive structure 2521 and the eleventh conductive structure 2522.

For example, as shown in FIG. 17, the initialization signal line INT is configured to provide an initialization voltage to sub-pixels, the reference voltage signal line REF is configured to provide a reference voltage to sub-pixels, the first power supply voltage signal line connection line is configured to electrically connect the first power supply voltage signal lines ELVDD arranged in the first direction, the light-emitting control line EML is configured to provide a light-emitting control signal to pixel circuits, and the data line connection line is configured to connect data lines that are adjacent in the first direction X and extend in the second direction Y.

It should be noted that in some drawings of the embodiments of the present disclosure, the first direction X and the second direction Y are shown in the planar diagrams, and a third direction Z is also shown in some cross-sectional diagrams. Both the first direction X and the second direction Y are directions parallel to the main surface of the base substrate BS. The third direction Z is a direction perpendicular to the main surface of the base substrate BS. For example, the first direction X intersects with the second direction Y, and the third direction Z is perpendicular to the first direction X and perpendicular to the second direction Y. The embodiments of the present disclosure are described by taking the first direction X and the second direction Y being perpendicular to each other as an example. The main surface of the base substrate BS is a surface of the base substrate BS used for manufacturing various components. For example, the upper surface of the base substrate BS is the main surface of the base substrate BS.

For example, FIG. 18 is a schematic diagram of a planar structure of a second conductive layer provided by at least one embodiment of the present disclosure. As shown in FIG. 18, the second conductive layer 26 includes a plurality of signal lines extending in the second direction Y and arranged in the first direction X. The signal lines include a data line 261 and a first power supply voltage signal line 262 arranged in the first direction X. In one pixel unit group, two adjacent display units share one data line 261.

For example, as shown in FIG. 18, the data lines 261 and the first power supply voltage signal lines 262 are evenly distributed, which can improve the flatness of the overall structure of the display substrate, thereby improving process performance, facilitating printing, and improving the display effect of the display substrate.

For example, with reference to FIG. 17 and FIG. 18, the data line connection line 2522 extending in the first direction connects two adjacent data lines 261 extending along the second direction Y and corresponding to two adjacent display units included in one pixel unit group, which reduces the overall resistance of the data lines 261. The first power supply voltage signal line connection line ELVDD extending in the first direction X connects adjacent first power supply voltage signal lines 262 extending in the second direction Y to form a mesh structure.

For example, as shown in FIG. 18, the signal line 271 includes a first connection portion 2711 and a second connection portion 2712, and in the first direction X, the width of the first connection portion 2711 is less than the width of the second connection portion 2712. For example, the signal line is the data line 261, the data line 261 includes two portions with different widths in the first direction X, and the two portions with different widths are respectively the first connection portion 2711 and the second connection portion 2712.

For example, in one example, the signal line is the first power supply voltage signal line 262, the first power supply voltage signal line 262 includes two portions with different widths in the first direction X, and the two portions with different widths are respectively the first connection portion 2711 and the second connection portion 2712.

For example, as shown in FIG. 18, in one example, the second conductive layer 26 further includes a connection structure 263 in a gap between the first power supply voltage signal line 262 and the data line 261 that are adjacent. With reference to FIG. 17 and FIG. 18, the orthographic projection of the connection structure 263 on the base substrate BS at least partially overlaps with the orthographic projection of the third gate line G3 on the base substrate BS. The first power supply voltage signal lines 262 and the data lines 261 are alternately arranged in the first direction X. The first power supply voltage signal line 262 is configured to provide the first power supply voltage to sub-pixels, the data line 261 is configured to provide the data signal to pixel circuits, ant the connection structure 263 is configured to be electrically connected to the first conductive layer 25.

For example, as shown in FIG. 18, in the first direction X, the width of the connection structure 263 is greater than or equal to the minimum spacing between adjacent signal lines 271, that is, in the first direction X, the width of the connection structure 263 is between the minimum distance and the maximum distance between adjacent signal lines 271.

For example, as shown in FIG. 18, in the first direction, the width of the connection structure 263, which is between the adjacent first power supply voltage signal line 262 and data line 261, is less than the maximum distance between the adjacent first power supply voltage signal line 262 and data line 261, and greater than the minimum distance between the adjacent first power supply voltage signal line 262 and data line 261.

For example, as shown in FIG. 18, in the second direction Y, the length of the connection structure 263 is less than the length of the first connection portion 2711.

For example, as shown in FIG. 18, the portion of the first power supply voltage signal line 262 corresponding to the connection structure 263 is the first connection portion 2711, and the portion of the first power supply voltage signal line 262 other than the first connection portion 2711 is the second connection portion 2712. The portion of the data line 261 corresponding to the connection structure 263 is the first connection portion 2711, and the portion of the data line 261 other than the first connection portion 2711 is the second connection portion 2712, that is, each of the first power supply voltage signal line 262 and the data line 261 includes a waisted portion, and the position of the waisted portion corresponds to the position of the connection structure 263.

For example, in one example, the display substrate further includes a first planarization layer and a first passivation layer between the second conductive layer and the first conductive layer, and a second planarization layer and a second passivation layer on a side of the second conductive layer away from the first conductive layer. For example, FIG. 19 is a schematic diagram of planar structures of a first planarization layer, a first passivation layer, a second planarization layer, and a second passivation layer provided by at least one embodiment of the present disclosure. In FIG. 19, an example is shown with vias formed in the first planarization layer, the first passivation layer, the second planarization layer, and the second passivation layer, and the structures corresponding to four display units are illustrated in FIG. 19. The first planarization layer 28 and the first passivation layer 29 have vias V21, V22, and V23, and the second planarization layer 30 and the second passivation layer 31 have the via V31.

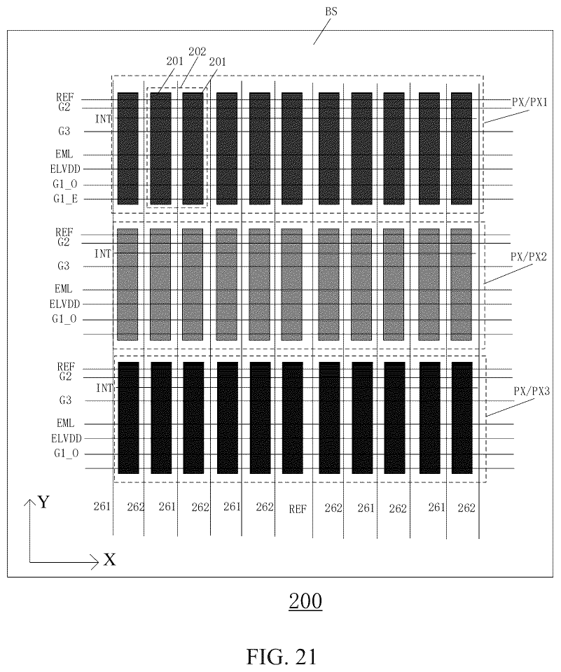

For example, FIG. 20 is a schematic diagram of a stacked layers structure including a semiconductor layer, a first metal layer, a second metal layer, a first conductive layer, and a second conductive layer corresponding to a plurality of sub-pixels in a display substrate provided by at least one embodiment of the present disclosure, and FIG. 21 is a simplified schematic diagram of a planar structure of a display substrate provided by at least one embodiment of the present disclosure. With reference to FIG. 20 and FIG. 21, the display substrate 200 includes a base substrate BS, and a plurality of sub-pixels PX on the base substrate BS. Although only three sub-pixels are shown in FIG. 20 and FIG. 21, the three sub-pixels are arranged sequentially in the second direction Y, and the three sub-pixels PX constitute a repeating unit. In the embodiments of the present disclosure, the number of sub-pixels is not limited to this, and there may also be more sub-pixels arranged in an array on the base substrate BS along the first direction X and the second direction Y that intersect each other. The display substrate includes a plurality of pixel circuits, each sub-pixel PX includes a plurality of display units 201, each display unit 201 is independently driven by a corresponding pixel circuit, and adjacent display units 201 constitute one pixel unit group 202. For example, in FIG. 20 and FIG. 21, each sub-pixel PX includes 11 display units 201, and the 11 display units 201 are sequentially arranged in the first direction X. However, the embodiments of the present disclosure do not limit the number of display units 201 included in each sub-pixel PX, and the number of display units 201 included in each sub-pixel PX may also be greater, thereby improving the display effect while ensuring the arrangement space of each display unit.

For example, with reference to FIG. 18, in the structures shown in FIG. 20 and FIG. 21, at least part of the plurality of signal lines 271 extend along the second direction Y, and two display units 201 included in at least one pixel unit group 202 are connected to the same signal line 271. In the second direction Y, each signal line 271 includes a first connection portion 2711 and a second connection portion 2712, and in the first direction X, the width of the first connection portion 2711 is less than the width of the second connection portion 2712. Along the first direction X, two adjacent display units 201 included in one pixel unit group 202 share one data line 261.

For example, FIG. 22 is a schematic diagram of a planar structure of another display substrate provided by at least one embodiment of the present disclosure. As shown in FIG. 22, a plurality of sub-pixels PX are arranged into a plurality of sub-pixel row groups PXG to achieve large-area display. For example, FIG. 22 includes two sub-pixel row groups PXG. The two sub-pixel row groups PXG respectively extend along the second direction Y and are arranged along the first direction X. Of course, the embodiments of the present disclosure are not limited to this, there may be more sub-pixel row groups PXG, and a plurality of sub-pixel row groups PXG are arranged in an array in the first direction X and the second direction Y.

For example, each sub-pixel row group PXG includes at least two rows of sub-pixels PX. In FIG. 22, each sub-pixel row group PXG includes three rows of sub-pixels PX. Each sub-pixel row group PXG corresponds to one lens portion, and a plurality of viewpoint regions formed by respective sub-pixel row groups through corresponding lens portions are continuously arranged along the first direction X, which can further improve the display effect.

For example, as shown in FIG. 22, each sub-pixel row group PXG includes a first color sub-pixel PX1, a second color sub-pixel PX2, and a third color sub-pixel PX3 that are sequentially arranged in the second direction Y. The sub-pixels PX in the same row arranged along the first direction X are sub-pixels of the same color, a first color sub-pixel row, a second color sub-pixel row and a third color sub-pixel row are arranged sequentially and repeatedly along the second direction Y, and each sub-pixel row group includes 3N rows of sub-pixels, where N is a positive integer. For example, in FIG. 22, two first color sub-pixels PX1 arranged in the same row along the first direction X form the first color sub-pixel row; two second color sub-pixels PX2 arranged in the same row arranged along the first direction X form the second color sub-pixel row; and two third color sub-pixels PX3 arranged in the same row along the first direction X form the third color sub-pixel row.

For example, in one example, the first color sub-pixel PX1 may be a sub-pixel that emits red light (i.e., a red sub-pixel), the second color sub-pixel PX2 may be a sub-pixel that emits green light (i.e., a green sub-pixel), and the third color sub-pixel PX3 may be a sub-pixel that emits blue light (i.e., a blue sub-pixel). The embodiments of the present disclosure are not limited to this. The colors of light emitted by sub-pixels of various colors may be interchanged. For example, the first color sub-pixel may be a sub-pixel that emits blue light, the second color sub-pixel may be a sub-pixel that emits red light, and the third color sub-pixel may be a sub-pixel that emits green light.

For example, the first color sub-pixel PX1 may include a plurality of display units R11, R12, R13, R14, R15, R16, R17, R18, R19, R20 and R21, the second color sub-pixel PX2 may include a plurality of display units G11, G12, G13, G14, G15, G16, G17, G18, G19, G20 and G21, and the third color sub-pixel PX3 may include a plurality of display units B11, B12, B13, B14, B15, B16, B17, B18, B19, B20 and B21.

For example, in FIG. 22, a plurality of red sub-pixels constitute a red sub-pixel row, a plurality of green sub-pixels constitute a green sub-pixel row, a plurality of blue sub-pixels constitute a blue sub-pixel row, and one red sub-pixel row, one green sub-pixel row and one blue sub-pixel row constitute a sub-pixel row group.

For example, as shown in FIG. 22, adjacent display units 201 included in each sub-pixel PX are closely arranged. For example, the close arrangement of adjacent display units 201 means that the spacing between adjacent display units 201 in each sub-pixel PX is very small, and no black region will be displayed after passing through a light splitting structure. Here, the “spacing” described in “the spacing between adjacent display units 201 in each sub-pixel PX is very small” refers to the spacing between the light-emitting regions of the display units. This spacing is easy to form moiré patterns after passing through the light splitting structure, which will affect the display effect of the display device formed finally.

For example, as shown in FIG. 22, the sub-pixels arranged along the first direction X are sub-pixels of the same color, and the first color sub-pixel row, the second color sub-pixel row and the third color sub-pixel row are arranged sequentially and repeatedly along the second direction Y. For example, each sub-pixel row group PXG includes 3N rows of sub-pixels, and N is a positive integer. FIG. 22 schematically shows that each sub-pixel row group PXG includes three rows of sub-pixels, but is not limited thereto and may also include six rows of sub-pixels or nine rows of sub-pixels.

For example, FIG. 23 is an enlarged schematic diagram of four display units in FIG. 20. It should be noted that FIG. 23 also shows the via structures included in the interlayer insulation layer 24, and the via structures included in the first planarization layer, the first passivation layer, the second planarization layer and the second passivation layer.

For example, as shown in FIG. 2, FIG. 11 and FIG. 23, the orthographic projection of the first active portion P1 on the base substrate BS respectively overlaps with the orthographic projections of the first gate line G1_O and the first gate line G1_E on the base substrate BS. The orthographic projection of the second active portion P2 on the base substrate BS overlaps with the orthographic projection of the second gate line G2 on the base substrate BS, the orthographic projection of the third active portion P3 on the base substrate BS overlaps with the orthographic projection of the third gate line G3 on the base substrate BS, the orthographic projection of the fourth active portion P4 on the base substrate BS overlaps with the orthographic projection of the light-emitting control line EML on the base substrate BS, and the orthographic projection of the fifth active portion P5 on the base substrate BS overlaps with the orthographic projection of the gate electrode T5g of the driving transistor T5 on the base substrate BS. Each of the first active portion P1, the second active portion P2, the third active portion P3, the fourth active portion P4, and the fifth active portion P5 extends in the second direction Y. Each active portion extends along the second direction Y, which facilitates regular arrangement of each transistor, thereby facilitating layout design. Although the base substrate BS is not shown in some planar diagrams, the plane on which the paper surface lies may be regarded as the main surface of the base substrate BS.

For example, as shown in FIG. 2, FIG. 11 and FIG. 23, portions of the semiconductor layer covered by the first metal layer 22 are semiconductor regions, which are formed as the channels of respective transistors, that is, the channel M1 to the channel M5. The portions of the semiconductor layer not covered by the first metal layer 22 are conductor regions, which are formed as the first electrode and the second electrode of each transistor, and the first electrode plate C11 of the first capacitor C1. The first metal layer 22 may be used as a mask to dope the semiconductor layer to convert the semiconductor material not blocked by the first metal layer 22 into a conductor, to form a semiconductor layer including respective semiconductor regions.

For example, as shown in FIG. 17 and FIG. 23, the first conductive portion 2511a is electrically connected to the semiconductor layer 21 through the first via structure V01, the second conductive portion 2512a is electrically connected to the first metal layer 22 through the second via structure V02, the third conductive portion 2513a is electrically connected to the semiconductor layer 21 through the third via structure V03, the fourth conductive portion 2514a is electrically connected to the first metal layer 22 through the fourth via structure V04, the fifth conductive portion 2515a is electrically connected to the second conductive layer 26 through the fifth via structure V05, the sixth conductive portion 2516a is electrically connected to the first metal layer 22 through the sixth via structure V06, the seventh conductive portion 2517a is electrically connected to the first metal layer 22 through the seventh via structure V07, the eighth conductive portion 2518a is electrically connected to the semiconductor layer 21 through the eighth via structure V08, the ninth conductive portion 2519a is electrically connected to the first metal layer 22 through the ninth via structure V09, the tenth conductive portion 2521a is electrically connected to the first metal layer 22 through the tenth via structure V10, and the eleventh conductive portion 2522a is electrically connected to the second conductive layer 26 through the eleventh via structure V11.

For example, as shown in FIG. 23, any two adjacent via structures among the above-mentioned first via structure V01, the second via structure V02, the third via structure V03, the fourth via structure V04, the fifth via structure V05, the sixth via structure V06, the seventh via structure V07, the eighth via structure V08, the ninth via structure V09, the tenth via structure V10, and the eleventh via structure V11 are arranged in a staggered layout manner in both the first direction X and the second direction Y, thereby ensuring that different layer structures are connected, the spacing between structures in the same layer can also be increased to avoid excessive deviations during the etching process for forming different structures, which in turn can improve the yield of the display substrate.

For example, as shown in FIG. 23, in one example, each of the first conductive structure 2511, the second conductive structure 2512, the third conductive structure 2513, the fourth conductive structure 2514, the seventh conductive structure 2517, the eighth conductive structure 2518, the ninth conductive structure 2519, and the tenth conductive structure 2521 is in a shape of a long strip extending in the first direction X; the width of the first conductive portion 2511a in the second direction Y is greater than the widths of other parts of the first conductive structure 2511 in the second direction Y, the width of the second conductive portion 2512a in the second direction Y is greater than the widths of other parts of the second conductive structure 2512 in the second direction Y, the width of the third conductive portion 2513a in the second direction Y is greater than the widths of other parts of the third conductive structure 2513 in the second direction Y, the width of the fourth conductive portion 2514a in the second direction Y is greater than the widths of other parts of the fourth conductive structure 2514 in the second direction Y, the width of the seventh conductive portion 2517a in the second direction Y is greater than the widths of other parts of the seventh conductive structure 2517 in the second direction Y, the width of the eighth conductive portion 2518a in the second direction Y is greater than the widths of other parts of the eighth conductive structure 2518 in the second direction Y, the width of the ninth conductive portion 2519a in the second direction Y is greater than the widths of other parts of the ninth conductive structure 2519 in the second direction Y, and the width of the tenth conductive portion 2521a in the second direction Y is greater than the widths of other parts of the tenth conductive structure 2521 in the second direction Y. In this way, in addition to the parts used for connection, the widths of other parts of the first conductive structure 2511, the second conductive structure 2512, the third conductive structure 2513, the fourth conductive structure 2514, the seventh conductive structure 2517, the eighth conductive structure 2518, the ninth conductive structure 2519 and the tenth conductive structure 2521 are all very small, so that the spacing between adjacent structures in the second direction Y can be widened, and the etching process becomes simple.

For example, as shown in FIG. 23, the fifth conductive structure 2515, the sixth conductive structure 2516, and the eleventh conductive structure 2522 each include block structures spaced apart from each other in the first direction X, the fifth conductive portion 2515a is at a middle position of respective block structures included in the fifth conductive structure 2515, the sixth conductive portion 2516a is at a middle position of respective block structures included in the sixth conductive structure 2516, and the fifth conductive portion 2515a and the sixth conductive portion 2516a are arranged in a staggered manner in the first direction X; and in each of block structures included in the eleventh conductive structure 2522, two eleventh conductive portions 2522a are respectively at both ends of a corresponding block structure along the first direction X.

For example, as shown in FIG. 23, in the first direction X, the first conductive portion 2511a, the second conductive portion 2512a, the third conductive portion 2513a, the fourth conductive portion 2514a, the fifth conductive portion 2515a, the sixth conductive portion 2516a, the seventh conductive portion 2517a, the eighth conductive portion 2518a, and the eleventh conductive portion 2522a included in any two adjacent display units 201 are all axially symmetrical with respect to a straight line that is between the two adjacent display units 201 and extending in the second direction Y.

For example, as shown in FIG. 23, one of the two adjacent display units 201 in the first direction X includes the ninth conductive portion 2519a, and the other of the two adjacent display units 201 includes the tenth conductive portion 2521a.

For example, with reference to FIG. 19 and FIG. 23, the second conductive layer 26 is electrically connected to the first conductive layer 25 through the via V21 and the via V22. The data line 261 is electrically connected to the data line connection line 2522 through the via V23. The second conductive layer 26 is electrically connected to the first electrode E1 of the light-emitting element 200b through the via V31.

For example, with reference to FIG. 3, in one example, each display unit 201 includes a light-emitting element 100b. The light-emitting element 100b is electrically connected to a corresponding pixel circuit 100a. The pixel circuit 100a is configured to drive the light-emitting element 100b. The light-emitting element 100b includes the first electrode E1, the second electrode E2, and the light-emitting functional layer EL between the first electrode E1 and the second electrode E2. The pixel circuit 100a includes the driving circuit 65, the driving circuit 65 includes the driving transistor T5, and the first electrode E1 of the light-emitting element 100b is electrically connected to the first electrode T5a of the driving transistor T5.

For example, the light-emitting functional layer EL includes a plurality of layers, such as a light-emitting layer (light-emitting material layer). The light-emitting functional layer may also include at least one of a hole injection layer, a hole transport layer, an electron transport layer, an electron injection layer, and the like. The light-emitting functional layer may be selected as needed.

For example, in one example, with reference to FIG. 3, the pixel circuit 100a further includes the light-emitting control circuit 64, the data writing circuit 61, the first reset circuit 62, the second reset circuit 63, the first storage circuit 66 and the second storage circuit 67.

For example, with reference to FIG. 3, the light-emitting control circuit 64 includes the light-emitting control transistor T4, the data writing circuit 61 includes the data writing transistor T1, the first reset circuit 62 includes the first reset transistor T2, the second reset circuit 63 includes the second reset transistor T3, the first storage circuit 66 includes the first capacitor C1, and the second storage circuit 62 includes the second capacitor C2.

For example, in one example, with reference to FIG. 3, the light-emitting control transistor T4 is electrically connected to the second electrode T5b of the driving transistor T5, and is configured to transmit the first power supply voltage to the second electrode T5b of the driving transistor T5 in response to the light-emitting control signal. The data writing transistor T1 is electrically connected to the gate electrode of the driving transistor T5, and is configured to write the data signal Vdt to the gate electrode T5g of the driving transistor T5 in response to the first scanning signal SCAN1. The first reset transistor T2 is electrically connected to the gate electrode T5g of the driving transistor T5, and is configured to transmit the reference voltage Vref to the gate electrode T5g of the driving transistor T5 in response to the second scanning signal SCAN2. The second reset transistor T3 is electrically connected with the first electrode E1 of the light-emitting element 100b, and is configured to transmit the initialization voltage Vini to the first electrode E1 of the light-emitting element 100b in response to the third scanning signal SCAN3.

For example, in one example, with reference to FIG. 3, the first electrode plate C11 of the first capacitor C1 is electrically connected to the gate electrode T5g of the driving transistor T5, the second electrode plate C12 of the first capacitor C1 is electrically connected to the first electrode T5a of the driving transistor T5, and the first capacitor C1 is configured to store the data signal. The first electrode plate C21 of the second capacitor C2 is electrically connected to the first electrode E1 of the light-emitting element 100b, and the second electrode plate C22 of the second capacitor C2 is electrically connected to the second electrode E2 of the light-emitting element 100b.

For example, in one example, as shown in FIG. 12 and FIG. 23, the gate electrode T11g of the data writing transistor T1 included in one of the adjacent display units 201 is electrically connected to the first gate line portion G1_O, or the gate electrode T12g of the data writing transistor T1 included in the other of the adjacent display units 201 is electrically connected to the second gate line portion G1_E. The gate electrode T2g of the first reset transistor T2 is electrically connected to the second gate line G2, and the first electrode T2a of the first reset transistor T2 is electrically connected to the reference voltage signal line REF. The gate electrode T3g of the second reset transistor T3 is electrically connected to the third gate line G3, and the second electrode T3b of the second reset transistor T3 is electrically connected to the initialization signal line INT. The gate electrode T4g of the light-emitting control transistor T4 is electrically connected to the light-emitting control line EML, and the first electrode T4a of the light-emitting control transistor T4 is electrically connected to the first power supply voltage signal line.

For example, as shown in FIG. 12, the gate electrodes (T11g, T12g) of the data writing transistor T1 include two rows of gate electrodes, one row of gate electrodes are gate electrodes T11g of the display units 201 in odd-numbered columns, and the other row of gate electrodes are gate electrodes T12g of the display units 201 in even-numbered columns.

For example, in one example, as shown in FIG. 12, the gate electrode T11g of the data writing transistor T1 included in one of adjacent display units 201, and the gate electrode T12g of the data writing transistor T1 included in the other of the adjacent display units 201 are spaced apart from each other in the first direction X. Thus, it can be ensured that the gate electrodes T11g/T12g of adjacent data writing transistors T1 are staggered and evenly distributed, which increases the spacing between structures in the same layer.

For example, with reference to FIG. 2, FIG. 12, FIG. 17 and FIG. 23, the gate electrode T2g of the first reset transistor T2 is in a shape of a long strip and extends in the first direction X, and the orthographic projection of the second gate line G2 on the base substrate BS is within the orthographic projection of the gate electrode T2g of the first reset transistor T2 on the base substrate BS.

For example, as shown in FIG. 23, the second gate line G2 and the gate electrode T2g of the first reset transistor T2 utilize the first conductive layer and the first metal layer to achieve double-layer metal wiring, which can not only uniformize the pattern distribution, but also prevent an excessive arrangement density of structures in the first conductive layer and the first metal layer.

For example, with reference to FIG. 2, FIG. 12, FIG. 17 and FIG. 23, in the second direction Y, the orthographic projection of the gate electrode T2g of the first reset transistor T2 on the base substrate BS is between the orthographic projection of the reference voltage signal line REF on the base substrate BS and the orthographic projection of the initialization signal line INT on the base substrate BS; and the orthographic projection of the gate electrode T3g of the second reset transistor T3 on the base substrate BS is on a side of the orthographic projection of the initialization signal line INT on the base substrate BS away from the orthographic projection of the reference voltage signal line REF on the base substrate BS.

For example, with reference to FIG. 2, FIG. 11, FIG. 12, FIG. 13, FIG. 17 and FIG. 23, the orthographic projection of the first active portion Pl on the base substrate BS overlaps with the orthographic projection of the first gate line G1_O/G_E on the base substrate BS, the orthographic projection of the second active portion P2 on the base substrate BS overlaps with the orthographic projection of the second gate line G2 on the base substrate BS, the orthographic projection of the third active portion P3 on the base substrate BS overlaps with the orthographic projection of the third gate line G3 on the base substrate BS, the orthographic projection of the fourth active portion P4 on the base substrate BS overlaps with the orthographic projection of the light-emitting control line EML on the base substrate BS, and the orthographic projection of the fifth active portion P5 on the base substrate BS overlaps with the orthographic projection of the gate electrode T5g of the driving transistor T5 on the base substrate BS; and each of the first active portion P1, the second active portion P2, the third active portion P3, the fourth active portion P4, and the fifth active portion P5 extends along the second direction Y and includes a channel, and a first electrode and a second electrode on both sides of the channel.

For example, FIG. 24 is a schematic diagram of a planar structure of a display substrate provided by at least one embodiment of the present disclosure. As shown in FIG. 24, only the first electrode of the light-emitting element is shown in the schematic diagram of the planar structure of the display substrate, and other structures are not shown. The display substrate 200 further includes a display region 250 and a peripheral region 260 surrounding a periphery of the display region 250. In the display region 250, first electrodes E1 of two light-emitting elements 100b adjacent in the first direction X have first spacing d1 in the first direction X, first electrodes E1 of two light-emitting elements 100b adjacent in the second direction Y have second spacing d2 in the second direction Y, and the first spacing d1 is less than the second spacing d2.

For example, FIG. 25 is a schematic diagram of a planar structure of a first electrode of a light-emitting element provided by at least one embodiment of the present disclosure. As shown in FIG. 25, in the second direction Y, in the peripheral region 260, the spacing between the first electrodes E1 of two light-emitting elements 100b adjacent in the second direction Y increases in a direction away from the display region 250. For example, in FIG. 25, in the second direction Y, that is, in the direction away from the display region 250, in the peripheral region 260, adjacent light-emitting elements 100b have second spacing d21, second spacing d22 and second spacing d23 between the adjacent light-emitting elements 100b in sequence, the second spacing d21 is less than the second spacing d22, and the second spacing d22 is less than the second spacing d23, which can form a gradient etching environment to increase the uniformity of the etching.

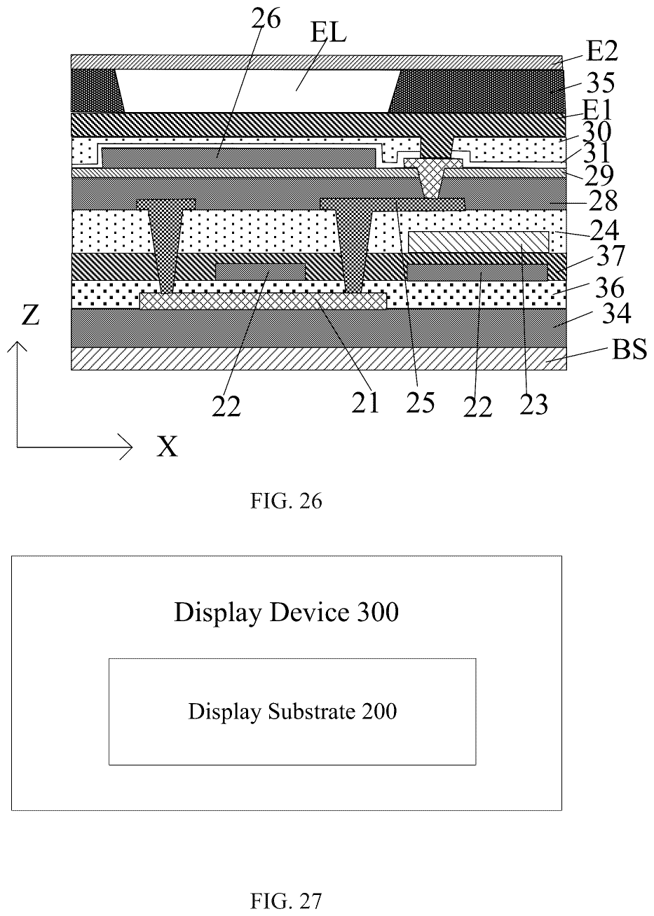

For example, FIG. 26 is a schematic diagram of a cross-sectional structure of a display substrate provided by at least one embodiment of the present disclosure. As shown in FIG. 26, a buffer layer 34, a semiconductor layer 21, a first gate insulation layer 36, a first metal layer 22, a second gate insulation layer 37, a second metal layer 23, an interlayer insulation layer 24, a first conductive layer 25, a first planarization layer 28, a first passivation layer 29, a second conductive layer 26, a second passivation layer 31, a second planarization layer 30, a first electrode E1 of a light-emitting element 100b, a pixel definition layer 35, a light-emitting functional layer EL, and a second electrode E2 of the light-emitting element 100b are sequentially provided on the base substrate BS.

As shown in FIG. 26, the third direction Z is a direction perpendicular to the main surface of the base substrate BS. As can be seen from FIG. 26, there is no overlap of vias or via structures in the third direction Z.

At least one embodiment of the present disclosure further provides a display device, and the display device includes the display substrate described in any one of the above embodiments. For example, FIG. 27 is a schematic diagram of a planar structure of a display device provided by at least one embodiment of the present disclosure, as shown in FIG. 27, the display device 300 includes the display substrate 200 in any of the above embodiments. The display device 300 may further include a functional component on a side of the base substrate away from the light-emitting element. For example, the functional component includes at least one of a camera module (for example, a front camera module), a 3D structured light module (for example, a 3D structured light sensor), a time-of-flight 3D imaging module (for example, a time-of-flight sensor), an infrared sensing module (for example, an infrared sensing sensor) and the like. The display device may also be any product or component with a display function such as a smartphone, a tablet computer, a television, a monitor, a notebook computer, a digital photo frame, a navigator, etc.

For example, the display device provided by the embodiments of the present disclosure is a 3D display device. The plurality of display units included in each sub-pixel can respectively display images corresponding to the left and right eyes of the human eyes. Therefore, the plurality of viewpoint image information displayed by each sub-pixel can form a naked-eye 3D image after passing through the corresponding lens portions.

The sub-pixels in the embodiments of the present disclosure may be red sub-pixels (R), green sub-pixels (G) and blue sub-pixels (B) in the display device (such as an organic light-emitting diode display device or a liquid crystal display device, etc.), and the display units in the sub-pixels are independent display units formed after dividing the sub-pixels in the display device to achieve subdivision of the sub-pixels.

The display substrate and the display device provided by at least one embodiment of the present disclosure have at least one of the following beneficial technical effects.

(1) The display substrate provided by at least one embodiment of the present disclosure enables display units included in at least one pixel unit group to be connected to the same signal line, and the signal line extending in the second direction includes a first connection portion and a second connection portion that have different widths in the first direction, where the width of the first connection portion is less than the width of the second connection portion. This can increase the spacing between structures in the same layer, reduce process defects, and reduce the load on signal line.

(2) In the display substrate provided by at least one embodiment of the present disclosure, any two adjacent via structures V0 in the first direction X or the second direction Y are spaced apart from each other. This staggered layout of vias not only ensures that different layers can be connected, but also increases the spacing between adjacent structures, thereby improving the yield of the display substrate.

(3) In the display substrate provided by at least one embodiment of the present disclosure, the data lines and the first power supply voltage signal lines are evenly distributed, which can improve the flatness of the overall structure of the display substrate, thereby improving process performance, facilitating printing, and improving the display effect of the display substrate.

The following statements should be noted:

(1) The drawings involve only the structure(s) in connection with the embodiment(s) of the present disclosure, and other structure(s) can be referred to common design(s).

(2) For clarity, in the drawings used to describe the embodiments of the present disclosure, the thicknesses of layers or regions are enlarged or reduced, that is, the drawings are not drawn to actual scale.

(3) In case of no conflict, features in one embodiment or in different embodiments can be combined to obtain new embodiments.

What have been described above are only specific implementations of the present disclosure, the protection scope of the present disclosure is not limited thereto, and the protection scope of the present disclosure should be based on the protection scope of the claims.

1. A display substrate, comprising:
a base substrate;
a plurality of sub-pixels, arranged in an array along a first direction and a second direction that intersect each other on the base substrate, and comprising a plurality of pixel circuits,
wherein each of the sub-pixels comprises a plurality of display units, each of the display units is independently driven by a corresponding pixel circuit, and adjacent display units form a pixel unit group; and
a plurality of signal lines, wherein at least part of the signal line extends along the second direction, display units comprised in at least one pixel unit group are connected to a same signal line, and in the second direction, the signal line comprises a first connection portion and a second connection portion, and in the first direction, a width of the first connection portion is less than a width of the second connection portion.

2. The display substrate according to claim 1, wherein the display substrate comprises a first conductive layer and a functional layer stacked on the base substrate, the first conductive layer comprises a plurality of conductive structures arranged in the second direction, each of the conductive structures comprises a conductive portion electrically connected to the functional layer through a via structure, and conductive portions adjacent to each other in the second direction are spaced apart in the first direction.

3. The display substrate according to claim 2, wherein the functional layer comprises a semiconductor layer, a first metal layer, and a second conductive layer stacked on the base substrate;
the conductive structure comprises a first conductive structure, a second conductive structure, a third conductive structure, a fourth conductive structure, a fifth conductive structure, a sixth conductive structure, a seventh conductive structure, an eighth conductive structure, a ninth conductive structure, a tenth conductive structure, and an eleventh conductive structure arranged sequentially in the second direction;
the conductive portion comprises a first conductive portion, a second conductive portion, a third conductive portion, a fourth conductive portion, a fifth conductive portion, a sixth conductive portion, a seventh conductive portion, an eighth conductive portion, a ninth conductive portion, a tenth conductive portion, and an eleventh conductive portion; and the first conductive portion, the second conductive portion, the third conductive portion, the fourth conductive portion, the fifth conductive portion, the sixth conductive portion, the seventh conductive portion, the eighth conductive portion, the ninth conductive portion, the tenth conductive portion, and the eleventh conductive portion are respectively a part of the first conductive structure, the second conductive structure, the third conductive structure, the fourth conductive structure, the fifth conductive structure, the sixth conductive structure, the seventh conductive structure, the eighth conductive structure, the ninth conductive structure, the tenth conductive structure, and the eleventh conductive structure;
the via structure comprises a first via structure, a second via structure, a third via structure, a fourth via structure, a fifth via structure, a sixth via structure, a seventh via structure, an eighth via structure, a ninth via structure, a tenth via structure, and an eleventh via structure;
the first conductive portion is electrically connected to the semiconductor layer through the first via structure, the second conductive portion is electrically connected to the first metal layer through the second via structure, the third conductive portion is electrically connected to the semiconductor layer through the third via structure, the fourth conductive portion is electrically connected to the first metal layer through the fourth via structure, the fifth conductive portion is electrically connected to the second conductive layer through the fifth via structure, the sixth conductive portion is electrically connected to the first metal layer through the sixth via structure, the seventh conductive portion is electrically connected to the first metal layer through the seventh via structure, the eighth conductive portion is electrically connected to the semiconductor layer through the eighth via structure, the ninth conductive portion is electrically connected to the first metal layer through the ninth via structure, the tenth conductive portion is electrically connected to the first metal layer through the tenth via structure, and the eleventh conductive portion is electrically connected to the second conductive layer through the eleventh via structure; and
any two adjacent portions among the first conductive portion, the second conductive portion, the third conductive portion, the fourth conductive portion, the fifth conductive portion, the sixth conductive portion, the seventh conductive portion, the eighth conductive portion, the ninth conductive portion, the tenth conductive portion, and the eleventh conductive portion in the second direction are spaced apart in the first direction.

4. The display substrate according to claim 3, wherein each of the first conductive structure, the second conductive structure, the third conductive structure, the fourth conductive structure, the seventh conductive structure, the eighth conductive structure, the ninth conductive structure, and the tenth conductive structure is in a shape of a long strip extending in the first direction;
a width of the first conductive portion in the second direction is greater than widths of other parts of the first conductive structure in the second direction, a width of the second conductive portion in the second direction is greater than widths of other parts of the second conductive structure in the second direction, a width of the third conductive portion in the second direction is greater than widths of other parts of the third conductive structure in the second direction, a width of the fourth conductive portion in the second direction is greater than widths of other parts of the fourth conductive structure in the second direction, a width of the seventh conductive portion in the second direction is greater than widths of other parts of the seventh conductive structure in the second direction, a width of the eighth conductive portion in the second direction is greater than widths of other parts of the eighth conductive structure in the second direction, a width of the ninth conductive portion in the second direction is greater than widths of other parts of the ninth conductive structure in the second direction, and a width of the tenth conductive portion in the second direction is greater than widths of other parts of the tenth conductive structure in the second direction.

5. The display substrate according to claim 4, wherein the fifth conductive structure, the sixth conductive structure, and the eleventh conductive structure each comprise block structures spaced apart from each other in the first direction, the fifth conductive portion is at a middle position of respective block structures comprised in the fifth conductive structure, the sixth conductive portion is at a middle position of respective block structures comprised in the sixth conductive structure, and the fifth conductive portion and the sixth conductive portion are arranged in a staggered manner in the first direction; and
in each of block structures comprised in the eleventh conductive structure, two eleventh conductive portions are respectively at both ends of a corresponding block structure along the first direction.

6. The display substrate according to claim 3, wherein in the first direction, the first conductive portion, the second conductive portion, the third conductive portion, the fourth conductive portion, the fifth conductive portion, the sixth conductive portion, the seventh conductive portion, the eighth conductive portion, and the eleventh conductive portion comprised in any two adjacent display units are all axially symmetrical with respect to a straight line that is between the two adjacent display units and extending in the second direction.

7. The display substrate according to claim 6, wherein among the two adjacent display units in the first direction, one is electrically connected to the ninth conductive structure, and the other is electrically connected to the tenth conductive structure; and
in the second direction, spacing between the ninth conductive structure and the tenth conductive structure is greater than spacing between the ninth conductive structure and the eighth conductive structure, and also greater than spacing between the tenth conductive structure and the eleventh conductive structure.

8. The display substrate according to claim 2, further comprising a lens structure, configured to irradiate image light emitted from the plurality of sub-pixels to different viewpoint regions, wherein the lens structure comprises a plurality of lens portions arranged in the first direction and extending in the second direction; and
the plurality of sub-pixels are arranged into a plurality of sub-pixel row groups, the plurality of sub-pixel row groups extend in the second direction and are arranged in the first direction, each of the sub-pixel row groups comprises at least two rows of sub-pixels, each of the sub-pixel row groups corresponds to one of the plurality of lens portions, and a plurality of viewpoint regions formed by respective sub-pixel row groups through corresponding lens portions are continuously arranged along the first direction.

9. (canceled)

10. The display substrate according to claim 3, wherein each display unit comprises a light-emitting element, the light-emitting element is electrically connected to a corresponding pixel circuit, the pixel circuit is configured to drive the light-emitting element, and the light-emitting element comprises a first electrode, a second electrode, and a light-emitting functional layer between the first electrode and the second electrode; and
the pixel circuit comprises a driving circuit, the driving circuit comprises a driving transistor, and the first electrode of the light-emitting element is electrically connected to a first electrode of the driving transistor.

11. The display substrate according to claim 10, wherein the pixel circuit further comprises a light-emitting control circuit, a data writing circuit, a first reset circuit, and a second reset circuit;
the light-emitting control circuit comprises a light-emitting control transistor, the data writing circuit comprises a data writing transistor, the first reset circuit comprises a first reset transistor, and the second reset circuit comprises a second reset transistor;
the light-emitting control transistor is electrically connected to a second electrode of the driving transistor and is configured to transmit a first power supply voltage to the second transistor of the driving transistor in response to a light-emitting control signal;
the data writing transistor is electrically connected to a gate electrode of the driving transistor and is configured to write a data signal into the gate electrode of the driving transistor in response to a first scanning signal;
the first reset transistor is electrically connected to the gate electrode of the driving transistor and is configured to transmit a reference voltage to the gate electrode of the driving transistor in response to a second scanning signal; and
the second reset transistor is electrically connected to the first electrode of the light-emitting element and is configured to transmit an initialization voltage to the first electrode of the light-emitting element in response to a third scanning signal.

12. The display substrate according to claim 11, wherein the pixel circuit further comprises a first storage circuit and a second storage circuit;
the first storage circuit comprises a first capacitor, the second storage circuit comprises a second capacitor, a first electrode plate of the first capacitor is electrically connected to the gate electrode of the driving transistor, a second electrode plate of the first capacitor is electrically connected to the first transistor of the driving transistor, and the first capacitor is configured to store the data signal; and
a first electrode plate of the second capacitor is electrically connected to the first electrode of the light-emitting element, and a second electrode plate of the second capacitor is electrically connected to the second electrode of the light-emitting element.

13. The display substrate according to claim 12, wherein the second conductive layer comprises the signal lines, and the signal lines comprise a first power supply voltage signal line and a data line arranged in the first direction, and a connection structure provided in a gap between the first power supply voltage signal line and the data line that are adjacent to each other;
the first power supply voltage signal line and the data line both extend along the second direction, and a plurality of first power supply voltage signal lines and a plurality of data lines are alternately arranged in the first direction; and
the first power supply voltage signal line is configured to provide the first power supply voltage to the sub-pixel, the data line is configured to provide the data signal to the pixel circuit, and the connection structure is configured to be electrically connected to the first conductive layer.

14. The display substrate according to claim 13, wherein a part of the first power supply voltage signal line corresponding to the connection structure is the first connection portion, and a part of the first power supply voltage signal line other than the first connection portion is the second connection portion; and
a part of the data line corresponding to the connection structure is the first connection portion, and a part of the data line other than the first connection portion is the second connection portion.

15. The display substrate according to claim 14, wherein in the first direction, a width of the connection structure between the first power supply voltage signal line and the data line that are adjacent to each other is less than a maximum distance between the first power supply voltage signal line and the data line that are adjacent to each other, and greater than a minimum distance between the first power supply voltage signal line and the data line that are adjacent to each other.

16. The display substrate according to claim 13, wherein the first conductive structure, the second conductive structure, the third conductive structure, the fourth conductive structure, the fifth conductive structure, the sixth conductive structure, the seventh conductive structure, the eighth conductive structure, the ninth conductive structure, the tenth conductive structure, and the eleventh conductive structure are respectively a reference voltage signal line, a second gate line, an initialization signal line, a third gate line, a connection portion of a first electrode of the second reset transistor, a connection portion of a first electrode of the driving transistor, a light-emitting control line, a first power supply voltage signal line connection line, a first gate line portion, a second gate line portion, and a data line connection line; and
the initialization signal line is configured to provide an initialization voltage to the sub-pixel, the reference voltage signal line is configured to provide a reference voltage to the sub-pixel, the first power supply voltage signal line connection line is configured to electrically connect first power supply voltage signal lines arranged in the first direction, the light-emitting control line is configured to provide a light-emitting control signal to the pixel circuit, and the data line connection line is configured to connect data lines that are adjacent in the first direction and extend in the second direction.

17. The display substrate according to claim 16, wherein the first metal layer comprises a gate electrode of the first reset transistor, a gate electrode of the second reset transistor, the gate electrode of the driving transistor, a gate electrode of the light-emitting control transistor, as well as a gate electrode of the data writing transistor comprised in one of adjacent display units and a gate electrode of the data writing transistor comprised in the other of the adjacent display units, which are arranged sequentially in the second direction;
the gate electrode of the data writing transistor comprised in one of the adjacent display units is electrically connected to the first gate line portion, or the gate electrode of the data writing transistor comprised in the other of the adjacent display units is electrically connected to the second gate line portion;
the gate electrode of the first reset transistor is electrically connected to the second gate line, and a first electrode of the first reset transistor is electrically connected to the reference voltage signal line;
the gate electrode of the second reset transistor is electrically connected to the third gate line, a second electrode of the second reset transistor is electrically connected to the initialization signal line; and
the gate electrode of the light-emitting control transistor is electrically connected to the light-emitting control line, and a first electrode of the light-emitting control transistor is electrically connected to the first power supply voltage signal line.

18. The display substrate according to claim 17, wherein the gate electrode of the data writing transistor comprised in one of the adjacent display units, and the gate electrode of the data writing transistor comprised in the other of the adjacent display units are spaced apart from each other in the first direction.

19. (canceled)

20. (canceled)

21. The display substrate according to claim 16, wherein the semiconductor layer comprises a first active portion, a second active portion, a third active portion, a fourth active portion, and a fifth active portion;
an orthographic projection of the first active portion on the base substrate overlaps with an orthographic projection of the first gate line on the base substrate, an orthographic projection of the second active portion on the base substrate overlaps with the orthographic projection of the second gate line on the base substrate, an orthographic projection of the third active portion on the base substrate overlaps with an orthographic projection of the third gate line on the base substrate, an orthographic projection of the fourth active portion on the base substrate overlaps with an orthographic projection of the light-emitting control line on the base substrate, and an orthographic projection of the fifth active portion on the base substrate overlaps with an orthographic projection of the gate electrode of the driving transistor on the base substrate; and
each of the first active portion, the second active portion, the third active portion, the fourth active portion, and the fifth active portion extends along the second direction and comprises a channel, and a first electrode and a second electrode on both sides of the channel.

22. (canceled)

23. The display substrate according to claim 10, further comprising a display region and a peripheral region surrounding a periphery of the display region,
wherein in the display region, first electrodes of two light-emitting elements adjacent in the first direction have first spacing in the first direction, first electrodes of two light-emitting elements adjacent in the second direction have second spacing in the second direction, and the first spacing is less than the second spacing.

24. (canceled)

25. A display device, comprising the display substrate according to claim 1.
